(19) United States
(12) Patent Application Publication
(10) Pub. No.: US 2026/0247603 A1
(43) Pub. Date: Aug. 20, 2026

(54) SEMICONDUCTOR DEVICE

(71) Applicant: Samsung Electronics Co., Ltd., Suwon-si (KR)

(72) Inventor: Taemin Cha, Suwon-si (KR)

(21) Appl. No.: 19/529,841

(22) Filed: Feb. 4, 2026

(30) Foreign Application Priority Data
Feb. 17, 2025 (KR) 10-2025-0019972

(51) Int. Cl. H10B 12/00

(52) U.S. Cl. CPC H10B 12/315; H10B 12/50

(57) ABSTRACT

A semiconductor device is described including a substrate with a cell active pattern, a cell gate structure positioned on the cell active pattern, and a bit line structure connected to the cell active pattern. The cell gate structure includes a cell gate insulating layer positioned on the cell active pattern, a cell gate conductive layer positioned on the cell gate insulating layer, and a cell gate capping layer positioned on the cell gate conductive layer and including an insulating material and hydrogen.

### CROSS-REFERENCE TO RELATED APPLICATIONS

This application claims priority to and the benefit of Korean Patent Application No. 10-2025-0019972 filed with the Korean Intellectual Property Office on February 17, 2025, the entire contents of which are incorporated herein by reference.

### BACKGROUND

Semiconductors may be included in an intermediate region between a conductor and an insulator and may conduct electricity under certain conditions. Various semiconductor devices, for example, memory devices, may be manufactured using these semiconductor materials. Such semiconductor devices may be used in various electronic devices.

As electronic devices become more miniaturized and highly integrated, it is desired to to finely form the patterns that make up semiconductor devices. As the width of these micro-patterns gradually decreases, the manufacturing processes may become more difficult and the defect rate of semiconductor devices may increase.

### SUMMARY

One aspect of the present disclosure provides a semiconductor device that passivates dangling bonds present at the interface between the cell gate insulating layer and the cell active pattern with hydrogen, while improving hydrogen supply dispersion, and does not cause reliability degradation in an upper wiring structure, a data storage pattern, and a peripheral gate structure due to the hydrogen diffusion path.

The semiconductor device according to one aspect includes a substrate including a cell active pattern, a cell gate structure positioned on the cell active pattern, and a bit line structure connected to the cell active pattern, wherein the cell gate structure includes a cell gate insulating layer positioned on the cell active pattern, a cell gate conductive layer positioned on the cell gate insulating layer, and a cell gate capping layer positioned on the cell gate conductive layer and including an insulating material and hydrogen.

A semiconductor device according to another aspect includes a substrate, a bit line positioned on the substrate, spaced apart in a first direction, and extended in a second direction different from the first direction, a first word line and a second word line positioned on the bit line, extended in the first direction, and alternately spaced apart in the second direction, a first active pattern and a second active pattern positioned on the bit line, spaced apart in the first direction, positioned between the first word line and the second word line, and that the first active pattern is positioned closer to the first word line and the second active pattern is positioned closer to the second word line, a back gate electrode positioned on the bit line, extended in the first direction, and positioned between the first active pattern and the second active pattern, a gate hydrogen diffusion pattern positioned on the first word line and the second word line, and a back gate hydrogen diffusion pattern positioned on the back gate electrode, wherein the gate hydrogen diffusion pattern and the back gate hydrogen diffusion pattern include an insulating material and hydrogen.

A semiconductor device according to another aspect includes a substrate, a bit line positioned on the substrate, spaced apart in a first direction, and extended in a second direction different from the first direction, a first word line and a second word line positioned on the bit line, extended in the first direction, and alternately spaced apart in the second direction, a first active pattern and a second active pattern positioned on the bit line, spaced apart in the first direction, positioned between the first word line and the second word line, that the first active pattern is positioned closer to the first word line and the second active pattern is positioned closer to the second word line, a gate hydrogen diffusion pattern positioned on the first word line and the second word line, and a hydrogen diffusion blocking layer positioned on the gate hydrogen diffusion pattern, wherein the hydrogen diffusion blocking layer has a lower hydrogen diffusivity than the gate hydrogen diffusion pattern.

According to the implementations, provided is a semiconductor device that passivates the dangling bonds present at the interface between the cell gate insulating layer and the cell active pattern with hydrogen, while improving the hydrogen supply dispersion, and does not cause reliability degradation in an wiring structure, a data storage pattern, and peripheral gate structure due to the hydrogen diffusion path.

### BRIEF DESCRIPTION OF THE DRAWINGS

FIG. 1 is a plan view of a semiconductor device according to some implementations.

FIG. 2 is an enlarged view of the E1 region in FIG. 1.

FIG. 3 is a cross-sectional view taken along lines B-B' and C-C' of FIG. 2.

FIG. 4 is a cross-sectional view taken along line A-A' of FIG. 2.

FIG. 5 is a cross-sectional view taken along line B-B' of FIG. 2.

FIG. 6 is a cross-sectional view taken along line C-C' of FIG. 2.

FIG. 7 is a cross-sectional view of a semiconductor device according to some implementations, corresponding to FIG. 4.

FIG. 8 is a plan view of a semiconductor device according to some implementations.

FIG. 9 is a cross-sectional view taken along lines A-A’ and B-B’ of FIG. 8.

FIG. 10 is a cross-sectional view taken along the line C-C' of FIG. 8.

FIG. 11 is an enlarged view of a P1 region of FIG. 10.

FIG. 12 is a cross-sectional view of a semiconductor device according to some implementations, corresponding to FIG. 11.

FIG. 13 is a cross-sectional view of a semiconductor device according to some implementations, corresponding to FIG. 11.

FIG. 14 is a cross-sectional view of a semiconductor device according to some implementations, corresponding to FIG. 11.

### DETAILED DESCRIPTION

The present disclosure will be described more fully hereinafter with reference to the accompanying drawings, in which implementations of the present disclosure are shown. As those skilled in the art would realize, the described implementations may be modified in various different ways, all without departing from the spirit or scope of the present disclosure.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion and does not necessarily mean being disposed on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

In addition, in this specification, the phrase “on a plane” means viewing a target portion from the top, and the phrase “on a cross-section” means viewing a cross-section formed by vertically cutting a target portion from the side.

Additionally, throughout the specification, two directions that are parallel to the upper surface of the substrate and intersecting with each other are respectively defined as a first direction D1 and a second direction D2, and the direction perpendicular to the upper surface of the substrate is described as a third direction D3. For example, the first direction D1 and the second direction D2 may be orthogonal to each other.

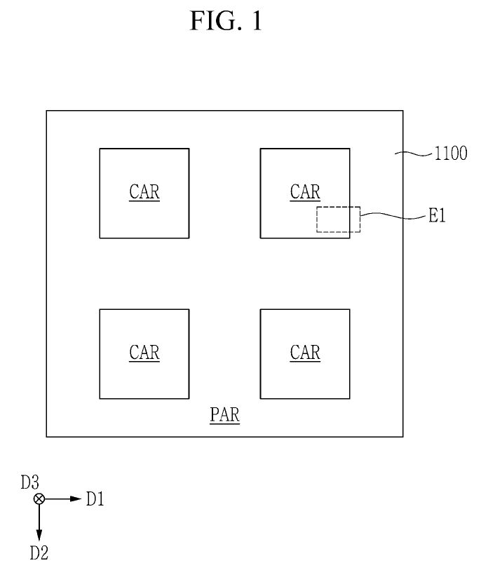

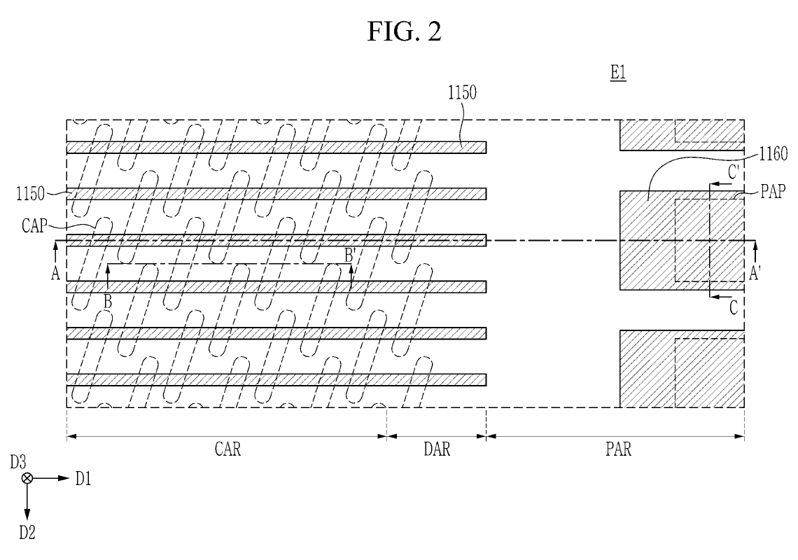

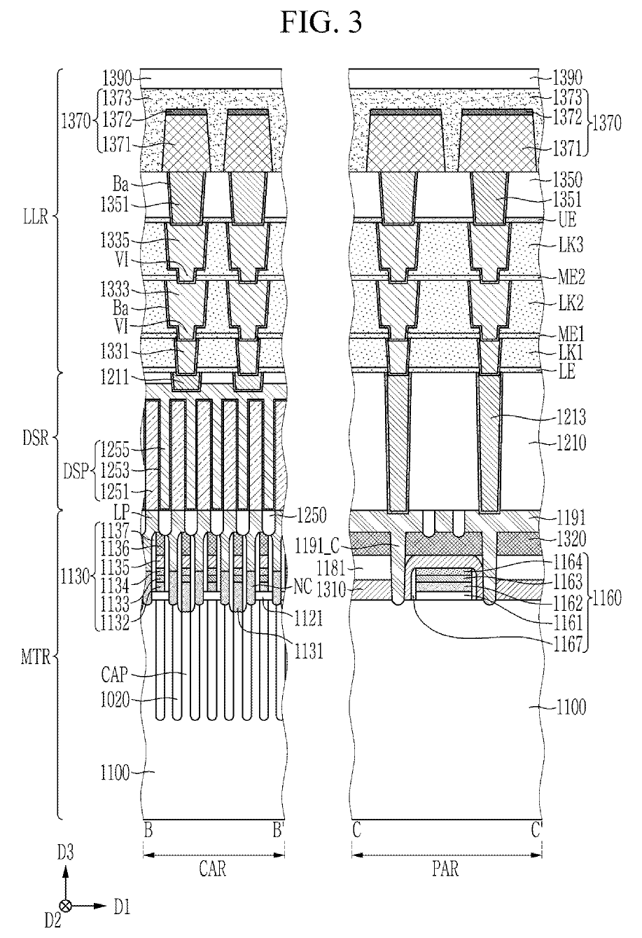

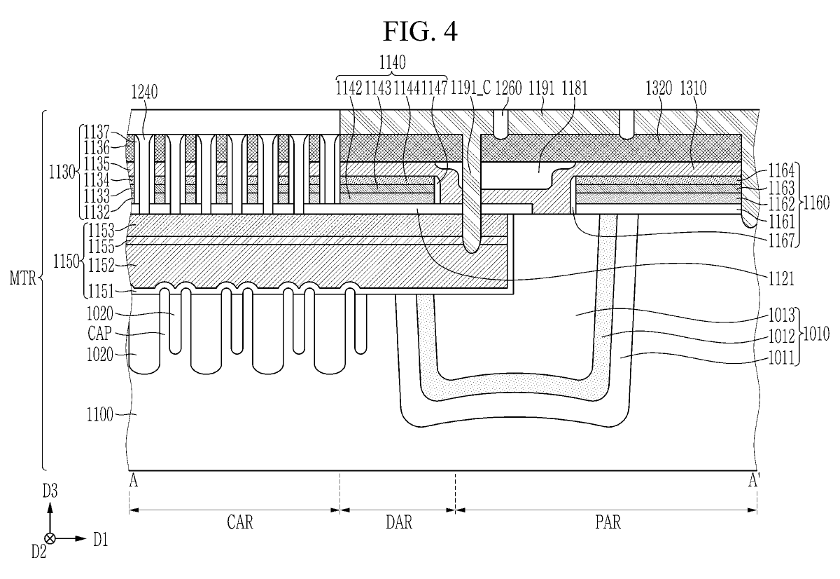

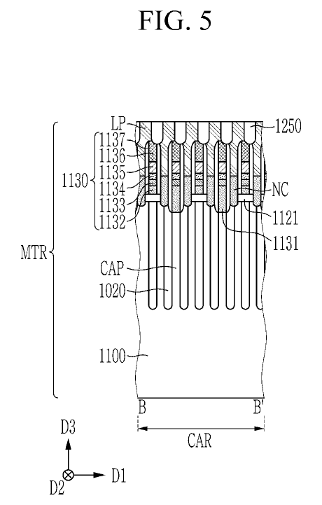

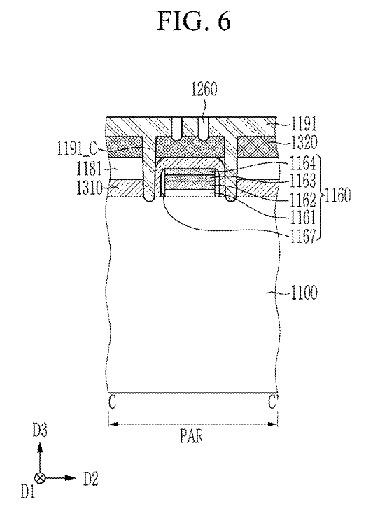

FIG. 1 is a plan view of a semiconductor device according to some implementations. FIG. 2 is an enlarged view of E1 region in FIG. 1. FIG. 3 is a cross-sectional view taken along lines B-B' and C-C' in FIG. 2, indicating a memory transistor region, a data storage pattern region, and a wiring region. FIG. 4 is a cross-sectional view taken along line A-A' in FIG. 2, in which the memory transistor region is enlarged. FIG. 5 is a cross-sectional view taken along line B-B' in FIG. 2, in which the memory transistor region is enlarged. FIG. 6 is a cross-sectional view taken along line C-C' in FIG. 2, in which the peripheral gate structure is enlarged.

Referring to FIGS. 1 to 6, the semiconductor device may include a memory transistor region MTR on a substrate 1100, a data storage pattern region DSR on the memory transistor region MTR, and a wire region LLR on the data storage pattern region DSR. The memory transistor region MTR may be a region including a plurality of memory transistors and/or circuits. The data storage pattern region DSR may be a region including a plurality of data storage patterns. The wire region LLR may be a region including a plurality of wires connected to a plurality of transistors and/or circuits.

For example, when the semiconductor device is a memory semiconductor device, the substrate 1100 of the memory transistor region MTR may include a cell region CAR including a cell array and a peripheral region PAR including peripheral circuits for driving the cell array. For example, the peripheral region PAR may surround the cell region CAR.

The cell region CAR may be an area where memory cells are arranged. The peripheral region PAR may be an area where word line drivers, sense amplifiers, row and column decoders, and control circuits are arranged. On the other hand, when the semiconductor device is a non-memory device, the memory transistor region MTR may not include the cell array of the cell region CAR.

The semiconductor device may include a substrate 1100. For example, the substrate 1100 may be a semiconductor substrate. For example, the substrate 1100 may include silicon, germanium, silicon-germanium, or a group III-V compound semiconductor substrate such as GaP or GaAs. In some implementations, the substrate 1100 may be a Silicon-On-Insulator (SOI) substrate or a Germanium-On-Insulator (GOI) substrate. The substrate 1100 may have a plate shape extending along a plane extending in the first direction D1 and the second direction D2.

The substrate 1100 may include cell regions CAR and a peripheral region PAR surrounding the cell regions CAR. The substrate 1100 may further include a dummy region DAR between the cell region CAR and the peripheral region PAR. The cell region CAR, the dummy region DAR, and the peripheral region PAR may be planarly distinguished by the first direction D1 and the second direction D2.

The cell region CAR of the substrate 1100 may include cell active patterns CAP. The upper portions of the cell region CAR of the substrate 1100 protruding in the third direction D3 may be defined as cell active patterns CAP. The cell active patterns CAP may be spaced apart from each other in the first direction D1.

The device isolation layer 1020 may be positioned within the cell region CAR of the substrate 1100. The device isolation layer 1020 may define cell active patterns CAP. Each of the cell active patterns CAP may be surrounded by the device isolation layer 1020. The device isolation layer 1020 may include an insulating material. For example, the device isolation layer 1020 may include silicon oxide, silicon nitride, or a combination thereof.

An insulating structure 1010 may be positioned within the substrate 1100. The insulating structure 1010 may be positioned between the cell region CAR and the peripheral region PAR. The insulating structure 1010 may also be positioned between the dummy region DAR and the peripheral region PAR. The insulating structure 1010 may include a first insulating layer 1011, a second insulating layer 1012 positioned on the first insulating layer 1011, and a third insulating layer 1013 placed on the second insulating layer 1012. For example, the first insulating layer 1011 may include silicon oxide, the second insulating layer 1012 may include silicon nitride, and the third insulating layer 1013 may include silicon oxide.

Cell gate structures 1150 may be positioned on a cell region CAR and a dummy region DAR of the substrate 1100. The cell gate structures 1150 may extend in a first direction D1. The cell gate structures 1150 may be spaced apart in a second direction D2. The cell gate structures 1150 may be positioned on a device separation layer 1020, an insulating structure 1010, and cell active patterns CAP. The cell gate structures 1150 may be buried gate structures embedded within the device separation layer 1020, the insulating structure 1010, and the cell active patterns CAP. A memory transistor may be defined by the cell gate structures 1150 and the cell active patterns CAP.

The cell gate structure 1150 may include a cell gate insulating layer 1151 positioned on the cell active pattern CAP, a cell gate conductive layer 1152 positioned on the cell gate insulating layer 1151, and a cell gate capping layer 1153 positioned on the cell gate conductive layer 1152.

The cell gate insulating layer 1151 may include an insulating material. For example, the cell gate insulating layer 1151 may include silicon oxide.

The cell gate conductive layer 1152 may include a conductive material. In some implementations, the cell gate structure 1150 may further include a second conductive layer 1155 positioned on the cell gate conductive layer 1152. The second conductive layer 1155 may be positioned between the cell gate conductive layer 1152 and the cell gate capping layer 1153. For example, the cell gate conductive layer 1152 may include a metal, and the second conductive layer 1155 may include polysilicon.

The cell gate capping layer 1153 may include an insulating material and hydrogen. In other words, the cell gate capping layer 1153 may be a hydrogen-rich (H-rich) insulating layer. The cell gate capping layer 1153 may provide hydrogen to boundaries between surrounding structures, for example, the cell gate insulating layer 1151 and the cell active pattern CAP, through annealing, and can passivate dangling bonds with hydrogen. The cell gate capping layer 1153 may still include hydrogen after providing hydrogen to the boundary between the cell gate insulating layer 1151 and the cell active pattern CAP.

For example, an annealing process for diffusing hydrogen may be performed at a pressure of 10 Torr to 40 Torr, or 20 Torr to 30 Torr, for 15 to 60 minutes, or 30 to 45 minutes, at a temperature of 400 °C to 475 °C or 375 °C to 400 °C. The annealing process may be performed at a temperature below the temperature range that induces crystallization of the cell active pattern CAP material, for example, below 600 °C.

The insulating material of the cell gate capping layer 1153 may include silicon nitride, silicon oxide, tetraethylortho silicate (TEOS), or a combination thereof. For example, by depositing SiH₄ and O₂ as raw materials, a hydrogen-rich cell gate capping layer 1153 including silicon oxide and hydrogen can be formed. Also, by depositing SiH₄ and NH₃ as raw materials, a hydrogen-rich cell gate capping layer 1153 including silicon nitride and hydrogen can be formed. At this time, deposition may use methods such as Atomic Pressure CVD (APCVD), Low Pressure CVD (LPCVD), Plasma Enhanced CVD (PECVD), or High Density Plasma CVD (HDPCVD). Alternatively, after depositing silicon oxide or silicon nitride, hydrogen can be plasma doped into silicon oxide or silicon nitride to form a hydrogen-rich cell gate capping layer 1153. For example, the cell gate capping layer 1153 may be a TEOS layer that includes tetraethylortho silicate (TEOS), and the cell gate capping layer 1153 may be a HDP layer that includes high density plasma CVD (HDP CVD) dielectric material.

The cell gate capping layer 1153 may include hydrogen, deuterium, tritium, or a combination thereof. Hydrogen may be a hydrogen atom or a hydrogen molecule. Since deuterium or tritium is heavier than hydrogen, if the cell gate capping layer 1153 includes deuterium or tritium, it can reduce the loss of deuterium or tritium into the air compared to when it includes hydrogen. For example, the cell gate capping layer 1153 may include 90 % or more of hydrogen with respect to the sum of hydrogen, deuterium, and tritium.

For example, the cell gate capping layer 1153 may include hydrogen in an amount of greater than 0 at% based on a total of the cell gate capping layer 1153, for example, 1 at% or more, 2 at% or more, 3 at% or more, or 4 at% or more, it may include hydrogen in an amount of 5 at% or less, for example, 4 at% or less, 3 at% or less, or 2 at% or less, and for example, it may include hydrogen in an amount of greater than 0 at% and less than or equal to 5 at%.

Moreover, the ratio of hydrogen intensity measured by the secondary ion mass spectroscopy (SIMS) of the cell gate capping layer 1153 to hydrogen intensity measured by the secondary ion mass spectroscopy (SIMS) of the cell active pattern CAP adjacent to the cell gate structure 1150 may be 10 or more : 1, for example, 100 or more : 1, or 1000 or more : 1.

For example, when the cell gate insulating layer 1151 includes silicon dioxide (SiO₂), and the cell active pattern CAP includes silicon (Si), hydrogen passivation may be performed on the dangling bonds present at the interface between silicon dioxide (SiO₂) and silicon (Si).

For this purpose, as described later, the upper wiring structure 1370 may include an upper wiring hydrogen diffusion layer 1372 including an insulating material and hydrogen that covers the upper wiring layer 1371. After forming the upper wiring hydrogen diffusion layer 1372 and performing annealing, the hydrogen of the upper wiring hydrogen diffusion layer 1372 may be supplied to the cell gate structure 1150 through the data storage pattern DSP in the cell area CAR and may diffuse to the boundary between the cell gate insulating layer 1151 and the cell active pattern CAP. Also, the hydrogen of the upper wiring hydrogen diffusion layer 1372 may be supplied to the end of the cell gate structure 1150 through the second lower contact 1213, the conductivity structures 1191, and the peripheral gate structure 1160 in the peripheral area PAR, and may diffuse to the boundary between the cell gate insulating layer 1151 and the cell active pattern CAP.

However, hydrogen diffusion from the upper wiring hydrogen diffusion layer 1372 may cause reliability degradation in the upper wiring structure 1370, the data storage pattern DSP, and the peripheral gate structure 1160 due to the hydrogen diffusion path. For example, in the upper wiring structure 1370, the hydrogen embrittlement of copper (Cu) wiring may degrade due to hydrogen diffusion, and moisture absorption vulnerability may occur due to degradation of interfacial adhesion. In the peripheral gate structure 1160, Negative Bias Temperature Instability (NBTI) may be deteriorated due to residual hydrogen from hydrogen diffusion, and in the data storage pattern DSP, the reliability may decrease as hydrogen ions (H⁺) bind to oxygen vacancies in the dielectric layer 1253 due to hydrogen diffusion.

According to some implementations, the cell gate structure 1150 includes a cell gate capping layer 1153 including the insulating material and hydrogen on a cell gate conductive layer 1152. Accordingly, hydrogen may be diffused from the cell gate capping layer 1153 to the boundary between the cell gate insulating layer 1151 and the cell active pattern CAP. By directly diffusing hydrogen from the cell gate capping layer 1153 to the boundary between the cell gate insulating layer 1151 and the cell active pattern CAP, it is advantageous in terms of hydrogen supply diffusion, and the reliability degradation of the upper wiring structure 1370, the data storage pattern DSP, and the peripheral gate structure 1160 resulting from the hydrogen diffusion path may not occur.

An insulating pattern 1121 may be positioned on the cell gate capping layer 1153 of the cell gate structure 1150, the device separation layer 1020, and the insulating structure 1010. The insulating pattern 1121 may include an insulating material. In some implementations, the insulating pattern 1121 may include a plurality of insulating layers.

The substrate 1100 may include a peripheral active pattern PAP within the peripheral region PAR. The upper portions of the peripheral region PAR of the substrate 1100 protruding in the third direction D3 may be defined as the peripheral active patterns PAP.

A peripheral gate structure 1160 may be positioned on the peripheral region PAR of the substrate 1100. The peripheral gate structure 1160 may be positioned on the peripheral active pattern PAP. In some implementations, the peripheral gate structure 1160 may be a gate of a peripheral transistor constituting a sub-word line driver.

The peripheral gate structure 1160 may include a peripheral gate insulating layer 1161, a first peripheral gate conductive layer 1163, a second peripheral gate conductive layer 1162, a peripheral gate capping layer 1164, and a gate sidewall capping structure 1167. The second peripheral gate conductive layer 1162 may be positioned on the peripheral gate insulating layer 1161, the first peripheral gate conductive layer 1163 may be positioned on the second peripheral gate conductive layer 1162, and the peripheral gate capping layer 1164 may be positioned on the first peripheral gate conductive layer 1163.

The peripheral gate insulating layer 1161 may include an insulating material. In some implementations, the peripheral gate insulating layer 1161 may include a plurality of insulating layers. For example, the peripheral gate insulating layer 1161 may include silicon dioxide (SiO₂) or hafnium oxide (HfO). The second peripheral gate conductive layer 1162 may include a conductive material. For example, the second peripheral gate conductive layer 1162 may include titanium nitride or polysilicon. The first peripheral gate conductive layer 1163 may include a conductive material. For example, the first peripheral gate conductive layer 1163 may include tungsten (W). The peripheral gate capping layer 1164 may include an insulating material. For example, the peripheral gate capping layer 1164 may include a silicon nitride.

The gate sidewall capping structure 1167 may include an insulating material. For example, the gate sidewall capping structure 1167 may include silicon nitride. For example, the gate sidewall capping structure 1167 may not include silicon oxide. The gate sidewall capping structure 1167 may include a plurality of insulating layers.

The dummy line structure 1140 may be positioned in the dummy area DAR. The dummy line structure 1140 may extend in the second direction D2. The dummy line structure 1140 may be positioned on the insulating pattern 1121. The dummy line structure 1140 may include the first dummy line conductive layer 1143, the second dummy line conductive layer 1142, the dummy line capping layer 1144, and the dummy line sidewall capping structure 1147. The second dummy line conductive layer 1142 may be positioned on the insulating pattern 1121, the first dummy line conductive layer 1143 may be positioned on the second dummy line conductive layer 1142, and the dummy line capping layer 1144 may be positioned on the first dummy line conductive layer 1143.

The dummy line sidewall capping structure 1147 may contact the sidewall of the dummy line capping layer 1144. The dummy line sidewall capping structure 1147 may contact the upper surface of the insulating pattern 1121. By the dummy line sidewall capping structure 1147, the sidewall of the dummy line capping layer 1144 may be separated from the peripheral etch stop layer 1310.

A peripheral etch stop layer 1310 may be positioned on the insulating pattern 1121, the dummy line structure 1140, and the peripheral gate structure 1160. The peripheral etch stop layer 1310 may extend in the first direction D1. The peripheral etch stop layer 1310 may include an insulating material. For example, the peripheral etch stop layer 1310 may include a nitride.

The peripheral etch stop layer 1310 may cover the dummy line structure 1140 and the peripheral gate structure 1160. The peripheral etch stop layer 1310 may contact with the upper surfaces of the peripheral gate capping layer 1164 and the dummy line capping layer 1144. The sidewalls of the peripheral gate insulating layer 1161, the second peripheral gate conductive layer 1162, the first peripheral gate conductive layer 1163, and the peripheral gate capping layer 1164 may be separated from the peripheral etch stop layer 1310 by the gate sidewall capping structure 1167.

By means of the dummy line sidewall capping structure 1147, the sidewalls of the second dummy line conductive layer 1142, the first dummy line conductive layer 1143, and the dummy line capping layer 1144 may be spaced apart from the peripheral etch stop layer 1310.

The filling insulating layer 1181 may be positioned on the peripheral etch stop layer 1310. The level of the upper surface of the filling insulating layer 1181 and the level of the upper surface of the peripheral etch stop layer 1310 may be the same. The filling insulating layer 1181 may include an insulating material.

A cover insulating layer 1320 may be positioned on a filling insulating layer 1181 and a peripheral etch stop layer 1310. The cover insulating layer 1320 may extend in a first direction D1. The cover insulating layer 1320 may include an insulating material. For example, the cover insulating layer 1320 may include silicon nitride.

Conductive structures 1191 may be positioned on the cover insulation layer 1320. The conductive structures 1191 may include a conductive material. At least one of the conductive structures 1191 may include a conductive contact 1191_C electrically connected to the cell gate structure 1150. Additionally, at least one of the conductive structures 1191 may include the conductive contact 1191_C electrically connected to the peripheral active pattern PAP.

First separation structures 1260 may be positioned on the cover insulation layer 1320. The first separation structure 1260 may separate the conductive structures 1191. The first separation structure 1260 may include an insulating material. In some implementations, the first separation structures 1260 and the subsequent second separation structure 1250 may have a unified structure that is connected without boundaries.

The bit line structures 1130 may be positioned on the cell region CAR of the substrate 1100. The bit line structures 1130 may extend in the second direction D2. The bit line structures 1130 may be spaced apart in the first direction D1. The bit line structure 1130 may be positioned on the insulating pattern 1121 and the cell active pattern CAP. The bit line structure 1130 may be electrically connected to the cell active pattern CAP.

The bit line structure 1130 may include a bit line contact 1131, a first bit line conductive layer 1133, a second bit line conductive layer 1132, a bit line insulating layer 1134, a cell etch stop layer 1135, a bit line capping layer 1136, and a bit line spacer 1137. The bit line contacts 1131 and second bit line conductive layers 1132 may be arranged alternately in a first direction D1. The bit line contact 1131 may be positioned on a cell active pattern CAP. The bit line contact 1131 may extend through the insulating pattern 1121.

The second bit line conductive layer 1132 may be positioned on the insulating pattern 1121. The first bit line conductive layer 1133 may be positioned on the bit line contact 1131 or the second bit line conductive layer 1132. The bit line insulating layer 1134 may be positioned on the first bit line conductive layer 1133. The cell etch stop layer 1135 may be positioned on the bit line insulating layer 1134. The bit line capping layer 1136 may be positioned on the cell etch stop layer 1135.

The first bit line conductive layer 1133, the second bit line conductive layer 1132, and the bit line insulating layer 1134 of the bit line structure 1130 may be similar in material and thickness to the first peripheral gate conductive layer 1163, the second peripheral gate conductive layer 1162, and the peripheral gate capping layer 1164 of the peripheral gate structure 1160. The cell etch stop layer 1135 may include the same material as the peripheral etch stop layer 1310. For example, the cell etch stop layer 1135 may include silicon nitride. In some implementations, the thickness of the cell etch stop layer 1135 may be the same as the thickness of the peripheral etch stop layer 1310. As an example, the thickness in the third direction D3 of the cell etch stop layer 1135 may be the same as the thickness in the third direction D3 of the portion of the peripheral etch stop layer 1310 overlapping with the peripheral gate structure 1160.

The bit line spacer 1137 may cover the sidewall of the second bit line conductive layer 1132, the sidewall of the first bit line conductive layer 1133, the sidewall of the bit line insulating layer 1134, the sidewall of the cell etch stop layer 1135, and the sidewall of the bit line capping layer 1136. The bit line spacer 1137 may include insulating material. In some implementations, the bit line spacer 1137 may include multiple insulating layers.

Node contacts NC may be positioned on a cell active pattern CAP. The node contacts NC may be positioned in between adjacent bit line structures 1130. The node contact NC may be positioned on the sidewall of the bit line structure 1130. The node contact NC may include a conductive material. For example, the node contact NC may include polysilicon.

Landing pads LP may be positioned on the node contacts NC. The landing pad LP may include a conducting material. For example, the landing pad LP may include metal. In some implementations, a metal silicide layer may be positioned between the node contact NC and the landing pad LP. In some implementations, a barrier layer may be positioned between the node contact NC and the landing pad LP.

Insulating fences 1240 may be positioned on the cell gate capping layers 1153. The insulating fence 1240 may be positioned between adjacent node contacts NC in the first direction D1. The insulating fence 1240 may include an insulating material.

The second separator structure 1250 may be positioned on the insulating fence 1240. The second separator structure 1250 may separate the landing pads LP from each other. The second separator structure 1250 may surround the landing pad LP. The second separator structure 1250 may include an insulating material.

The data storage patterns DSP may be positioned on the landing pads LP. The data storage patterns DSP may be electrically connected to the cell active patterns CAP through the landing pads LP and the node contacts NC. In some implementations, each of the data storage patterns DSP may be a capacitor including a lower electrode 1251, a dielectric layer 1253, and an upper electrode 1255. In this case, the semiconductor device including the data storage patterns DSP may be a dynamic random access memory (DRAM).

The lower electrode 1251 of the data storage pattern DSP, for example, may have a pillar shape or a closed-bottom cylinder shape. The lower electrode 1251, for example, may include impurity-doped polysilicon, metal, metal nitride, metal silicide, polysilicide, or a combination thereof.

The dielectric layer 1253 may conformally cover the lower electrode 1251. The dielectric layer 1253, for example, may include oxides, nitrides, silicides, oxynitrides, or silicate oxynitrides including hafnium Hf, aluminum Al, zirconium Zr, lanthanum La, or a combination thereof.

The upper electrode 1255 may cover the dielectric layer 1253. For example, in the case where the lower electrode 1251 has a closed-bottom cylinder shape, the upper electrode 1255 may fill the interior of the cylinder shape. The upper electrode 1255, for example, may include silicon germanium doped with impurities.

In some implementations, each of the data storage patterns DSP may include a magnetic tunnel junction pattern. In this case, a semiconductor device including the data storage patterns DSP may be a Magnetic Random Access Memory (MRAM). In some implementations, the data storage patterns DSP may include phase change material or a variable resistive material. In this example, a semiconductor device including the data storage patterns DSP may be a Phase-change Random Access Memory (PRAM) or a Resistive Random Access Memory (ReRAM). In some implementations, each of the data storage patterns DSP may encompass a variety of structures and/or materials for data storage.

An underlying interlayer insulating layer 1210 may cover the peripheral gate structure 1160 on the peripheral region PAR and the data storage pattern DSP on the cell region CAR. For example, the underlying interlayer insulating layer 1210 may include boro-phosphosilicate glass (BPSG), tonen silazene (TOSZ), undoped silicate glass (USG), spin-on glass (SOG), flowable oxide (FOX), tetraethylortho silicate (TEOS), high density plasma chemical vapor deposition (HDP CVD) dielectric material, or hydrogen silsesquioxane (HSQ).

The wire region LLR may include interlayer insulation layers, low dielectric constant layers, and wire layers formed therein. For example, the wire region LLR may include sequentially laminated first to third low dielectric constant layers LK1, LK2, LK3, an upper interlayer insulation layer 1350 positioned on the third low dielectric constant layer LK3, and an upper wiring structure 1370 positioned on the upper interlayer insulation layer 1350. The first low dielectric constant layer LK1, the second low dielectric constant layer LK2, and the third low dielectric constant layer LK3 may each have a first lower wiring layer 1331, a second lower wiring layer 1333, and a third lower wiring layer 1335 positioned therein respectively. The number of low dielectric constant layers and lower wiring layers is not limited and may be variously changed.

For example, the low dielectric constant layer refers to an insulating layer with a dielectric constant less than 4.4. For example, the first to third low dielectric constant layers LK1, LK2, LK3 may include SiCOH. The first to third underlying wiring layers 1331, 1333, 1335 may include copper Cu or tungsten W. The first to third low dielectric constant layers LK1, LK2, LK3 may be formed of the same material, but are not limited thereto, and some of the first to third low dielectric constant layers LK1, LK2, LK3 may be formed of materials with different dielectric constants or different compositions.

The second lower wiring layer 1333 and third lower wiring layer 1335 may include vias VI provided on the lower surface of a line type structure extending in one direction. The upper width of the first to third lower wiring layers 1331, 1333, 1335 may be greater than the lower width, but the disclosure is not limited to this example.

A portion of the first lower wiring layer 1331 on the cell region CAR may be connected to the upper portion of the data storage pattern DSP, for example, to the upper electrodes 1255 of capacitors, through the first lower contact 1211. A portion of the first lower wiring layer 1331 on the peripheral region PAR may be connected to the conductivity contact 1191_C, which is electrically connected to the peripheral active pattern PAP, through the second lower contact 1213. The lower surface of the second lower contact 1213 may be positioned at a level lower than the lower surface of the first lower contact 1211. The upper surfaces of the first and second lower contacts 1211, 1213 may be positioned substantially at the same level. The first and second lower contacts 1211, 1213 may include tungsten W, titanium Ti, tantalum Ta, or nitrides of these materials.

The lower interface layer LE may be positioned between the first low dielectric constant layer LK1 and the lower interlayer insulating layer 1210. The upper interface layer UE may be positioned between the third low dielectric constant layer LK3 and the upper interlayer insulating layer 1350. For example, the lower interface layer LE may be an interface layer contacting the bottom layer among the first to third low dielectric constant layers LK1, LK2, LK3, and the upper interface layer UE may be an interface layer contacting the upper layer among the first to third low dielectric constant layers LK1, LK2, LK3. The first and second intermediate interface layers ME1, ME2 may be positioned between the first to third low dielectric constant layers LK1, LK2, LK3. For example, the first intermediate interface layer ME1 may be positioned between the first low dielectric constant layer LK1 and the second low dielectric constant layer LK2, and the second intermediate interface layer ME2 may be positioned between the second low dielectric constant layer LK2 and the third low dielectric constant layer LK3. Some of the lower interface layer LE, upper interface layer UE, and first and second intermediate interface layers ME1, ME2 may include multiple insulating layers with different characteristics. For example, the upper interface layer UE may include multiple interface layers. In contrast, the lower interface layer LE and the first and second intermediate interface layers ME1, ME2 may be single layers. Each of the lower interface layer LE, upper interface layer UE, and the first and second intermediate interface layers ME1, ME2, for example, may include silicon nitride (SiN) or silicon carbonitride (SiCN). For example, the upper interface layer UE may include silicon nitride (SiN), and the lower interface layer LE, and the first and second intermediate interface layers ME1, ME2 may include silicon carbonitride (SiCN).

An upper interlayer insulating layer 1350 may be positioned on the third low dielectric constant layer LK3. The upper interlayer insulating layers 1350 may be insulating layers having a higher dielectric constant than the first to third low dielectric constant layers LK1, LK2, LK3. For example, each of the upper interlayer insulating layers 1350 may have a dielectric constant of 4.4 or more. The upper interlayer insulating layer 1350 may include boro-phosphosilicate glass (BPSG), tonen silazene (TOSZ), undoped silicate glass (USG), spin-on glass (SOG), flowable oxide (FOX), tetraethylortho silicate (TEOS), high density plasma CVD (HDP CVD) dielectric material, or hydrogen silsesquioxane (HSQ).

The upper contact 1351 may be positioned within the upper interlayer insulating layer 1350. The upper contact 1351 may extend through the upper interlayer insulating layer 1350 and the upper surface layer UE and may make contact with the third lower wiring layer 1335. The upper contact 1351 may be electrically connected to the first to third lower wiring layers 1331, 1333, 1335 and the first and second lower contacts 1211, 1213. For example, the upper contact 1351 may include tungsten (W), titanium (Ti), tantalum (Ta), or nitrides thereof.

At least a portion of the first and second lower contacts 1211, 1213, the first to third lower wiring layers 1331, 1333, 1335, or the upper contact 1351 may include a barrier layer Ba. The barrier layer Ba may be positioned on the lower surface and sidewalls of at least a portion of the first and second lower contacts 1211, 1213, the first to third lower wiring layers 1331, 1333, 1335, or the upper contact 1351. The barrier layer Ba may include conductive metal nitrides such as titanium nitride (TiN) or tantalum nitride (TaN).

The upper wiring structure 1370 may include an upper wiring layer 1371, an upper wiring hydrogen diffusion layer 1372, and an upper wiring hydrogen diffusion blocking layer 1373. The upper wiring structure 1370 may be positioned in the cell region CAR and/or the peripheral region PAR. Accordingly, the upper wiring layer 1371, the upper wiring hydrogen diffusion layer 1372, and the upper wiring hydrogen diffusion blocking layer 1373 may also be positioned in the cell region CAR and/or the peripheral region PAR.

The upper wiring layer 1371 may be positioned within the upper wiring hydrogen diffusion blocking layer 1373. The upper wiring layer 1371 may come into contact with the upper surface of the upper contact 1351. The upper wiring layer 1371 may be electrically connected to the upper contact 1351, first to third lower wiring layers 1331, 1333, 1335, and first and second lower contacts 1211, 1213. For example, the upper width of the upper wiring layer 1371 may be lower than the lower width.

For example, the upper wiring layer 1371 may include tungsten (W), titanium (Ti), tantalum (Ta), or nitrides thereof. In some implementations, the upper contact 1351 and the upper wiring layer 1371 may include a different conductivity material than the first to the third lower wiring layers 1331, 1333, 1335. For example, the first to third lower wiring layers 1331, 1333, 1335 may include a first metal, and the upper contact 1351 and the upper wiring layer 1371 may include a second metal different from the first metal. For example, the upper contact 1351 and the upper wiring layer 1371 may include aluminum (Al).

The upper wiring hydrogen diffusion layer 1372 may be positioned on the upper wiring layer 1371. The upper wiring hydrogen diffusion layer 1372 may conformally cover the upper surface of the upper wiring layer 1371. The upper wiring hydrogen diffusion layer 1372 may be positioned within the upper wiring hydrogen diffusion blocking layer 1373.

The upper wiring hydrogen diffusion layer 1372 may include an insulating material and hydrogen. In other words, the upper wiring hydrogen diffusion layer 1372 may be a hydrogen-rich (H-rich) insulating layer. Through annealing, the hydrogen in the upper wiring hydrogen diffusion layer 1372 may be supplied to the cell gate structure 1150 through the data storage pattern DSP in the cell region CAR and may diffuse up to the boundary between the cell gate insulating layer 1151 and cell active pattern CAP. Further, the hydrogen of the upper wiring hydrogen diffusion layer 1372 may be supplied to the end of the cell gate structure 1150 through the second lower contact 1213, conductivity structures 1191, and peripheral gate structures 1160 in the peripheral region PAR and may diffuse up to the boundary between the cell gate insulating layer 1151 and cell active pattern CAP. For example, if the cell gate insulating layer 1151 includes silicon dioxide (SiO₂), and the cell active pattern CAP includes silicon (Si), the dangling bonds existing at the interface between silicon dioxide (SiO₂) and silicon (Si) can be passivated with hydrogen. The upper wiring hydrogen diffusion layer 1372 may still include hydrogen even after diffusing hydrogen through annealing.

For example, an annealing process to diffuse hydrogen may be performed at a pressure of 10 Torr to 40 Torr, for example, 20 Torr to 30 Torr, for 15 to 60 minutes, for example, 30 to 45 minutes, at a temperature of 400°C to 475°C, for example, 375°C to 400°C. The annealing process may be performed at a temperature below the temperature range inducing crystallization of the cell active pattern CAP material for example, below 600°C.

The insulating material of the upper wiring hydrogen diffusion layer 1372 may include silicon nitride, silicon oxide, tetraethylortho silicate (TEOS), or a combination thereof. For example, when SiH₄ and O₂ are used as raw materials for deposition, a hydrogen-rich upper wiring hydrogen diffusion layer 1372 that includes silicon oxide and hydrogen may be formed. Also, if SiH₄ and NH₃ are used for deposition, a hydrogen-rich upper wiring hydrogen diffusion layer 1372 that includes silicon nitride and hydrogen may be formed. In this case, the deposition may methods such as Atomic Pressure CVD (APCVD), Low Pressure CVD (LPCVD), Plasma Enhanced CVD (PECVD), or High Density Plasma CVD (HDPCVD). Alternatively, after depositing silicon oxide or silicon nitride, the silicon oxide or silicon nitride may be doped with hydrogen using plasma doping to form the hydrogen-rich upper wiring hydrogen diffusion layer 1372.

For example, the upper wiring hydrogen diffusion layer 1372 may be a tetraethylortho silicate (TEOS) layer including TEOS, and the upper wiring hydrogen diffusion layer 1372 may be an HDP layer including high density plasma CVD (HDP CVD) dielectric material.

The upper wiring hydrogen diffusion layer 1372 may include hydrogen, deuterium, tritium, or a combination thereof. Hydrogen can be either atomic hydrogen or molecular hydrogen. Since deuterium or tritium is heavier than hydrogen, if the upper wiring hydrogen diffusion layer 1372 includes deuterium or tritium, the loss of deuterium or tritium into the air can be reduced compared to the case where only hydrogen is included. For example, the upper wiring hydrogen diffusion layer 1372 may include 90 % or more of hydrogen with respect to the sum of hydrogen, deuterium, and tritium.

For example, the upper wiring hydrogen diffusion layer 1372 may include hydrogen in an amount of greater than 0 at% based on a total of the upper wiring hydrogen diffusion layer 1372, for example, 1 at% or more, 2 at% or more, 3 at% or more, or 4 at% or more, it may include hydrogen in an amount of 5 at% or less, for example, 4 at% or less, 3 at% or less or 2 at% or less, and for example, it may include hydrogen in an amount of greater than 0 at% and less than or equal to 5 at%.

At this time, the upper wiring hydrogen diffusion layer 1372 may have a lower hydrogen concentration than the cell gate capping layer 1153. Accordingly, the main source of hydrogen may be the cell gate capping layer 1153, and the upper wiring hydrogen diffusion layer 1372 may be a secondary source of hydrogen. As mentioned above, hydrogen diffusion from the upper wiring hydrogen diffusion layer 1372 may cause reliability degradation in the upper wiring structure 1370, the data storage pattern DSP, and the peripheral gate structure 1160 due to the hydrogen diffusion path, therefore, the upper wiring hydrogen diffusion layer 1372 may assist the cell gate capping layer 1153.

The upper wiring hydrogen diffusion blocking layer 373 may be positioned on the upper interlayer insulating layer 1350. The upper wiring hydrogen diffusion blocking layer 1373 may cover the upper wiring layer 1371 and the upper wiring hydrogen diffusion blocking layer 1372.

For example, the upper wiring hydrogen diffusion blocking layer 1373 may have a lower hydrogen diffusivity than the upper wiring hydrogen diffusion layer 1372. The upper wiring hydrogen diffusion blocking layer 1373 may include silicon nitride, which has a low hydrogen diffusivity.

Herein, the hydrogen diffusivity refers to the diffusion rate of hydrogen, which is higher in silicon, germanium, or silicon oxide than in silicon nitride or dielectric layers such as Al₂O₃ or ZrO₂, and higher in metals than in silicon, germanium or silicon oxide. For example, the hydrogen diffusivity in silicon of molecular hydrogen (H₂) may be approximately 2.39E-07 cm²/s at 400 °C, the hydrogen diffusivity in silicon oxide of molecular hydrogen (H₂) may be approximately 2.43E-07 cm²/s at 400 °C, the hydrogen diffusivity in silicon nitride of molecular hydrogen (H₂) may be approximately 1.73E-25 cm²/s at 400 °C, the hydrogen diffusivity in Al₂O₃ of molecular hydrogen (H₂) may be approximately 9.32E-27 cm²/s at 400 °C, the hydrogen diffusivity in Aluminum (Al) of molecular hydrogen (H₂) may be approximately 7.03E-06 cm²/s at 400 °C, and the hydrogen diffusivity in Tungsten (W) of molecular hydrogen (H₂) may be approximately 4.84E-06 cm²/s at 400 °C.

The upper wiring hydrogen diffusion blocking layer 1373 may have a lower hydrogen concentration than the upper wiring hydrogen diffusion layer 1372. In other words, a hydrogen source such as SiH₄ or NH₃ may not be used when forming the upper wiring hydrogen diffusion blocking layer 1373. The upper wiring hydrogen diffusion blocking layer 1373 may include 1 at% or less of hydrogen based on a total of the upper wiring hydrogen diffusion blocking layer 1373, or may not include hydrogen. The upper wiring hydrogen diffusion blocking layer 1373 may prevent hydrogen from diffusing from the upper wiring hydrogen diffusion layer 1372 to above, for example, to the outside of the semiconductor device.

A passivation layer 1390 may be positioned on the upper wiring structure 1370. For example, the passivation layer 1390 may include silicon nitride (SiN). The hydrogen permeability of the passivation layer 1390 may be higher than the hydrogen permeability of the upper wiring hydrogen diffusion blocking layer 1373.

In some implementations, a semiconductor device may further include a dielectric layer positioned beneath the upper wiring structure 1370 in the cell region CAR of the substrate 1100.

The dielectric layer may include a first layer including aluminum oxide, a second layer including zirconium, or a composite layer where the first layer and second layer are alternately laminated. For example, the dielectric layer may be a ZrO₂/Al₂O₃ composite layer or a ZrO₂/Al₂O₃/ZrO₂ composite layer. A ZrO₂/Al₂O₃ composite layer is beneficial in blocking the diffusion path of hydrogen by utilizing the grain size difference between ZrO₂ and Al₂O₃. Therefore, such a dielectric layer may prevent the diffusion of hydrogen from the cell gate capping layer 1153 to the upper part, for example, to the upper wiring structure 1370.

For example, the dielectric layer may be positioned below the upper electrode 1255 of the data storage pattern DSP, and, for example, the dielectric layer may be the dielectric layer 1253 positioned between the lower electrode 1251 and the upper electrode 1255 of the data storage pattern DSP. In other words, the dielectric layer 1253 of the data storage pattern DSP may be a ZrO₂/Al₂O₃ composite layer or a ZrO₂/Al₂O₃/ZrO₂ composite layer. It is not limited to this example. The dielectric layer may be sequentially laminated first to third low dielectric constant layers LK1, LK2, LK3 of the wiring region LLR.

In the peripheral region PAR of the substrate 1100, such a dielectric layer may not be included. In particular, when the upper wiring structure 1370 includes an upper wiring hydrogen diffusion layer 1372, in other words, in case it is intended to diffuse hydrogen to the end of the cell gate structure 1150 through the second lower contact 1213, the conductive structures 1191, and the peripheral gate structures 1160 from the upper wiring hydrogen diffusion layer 1372, the peripheral region PAR of the substrate 1100 may not include a dielectric layer. However, even in this case, by including a dielectric layer in the cell region CAR of the substrate 1100, during the diffusion of hydrogen from the upper wiring hydrogen diffusion layer 1372, the degradation of reliability of the first to third lower wiring layers 1331, 1333, 1335 and the data storage pattern DSP in the cell region CAR due to the path of hydrogen diffusion may be prevented.

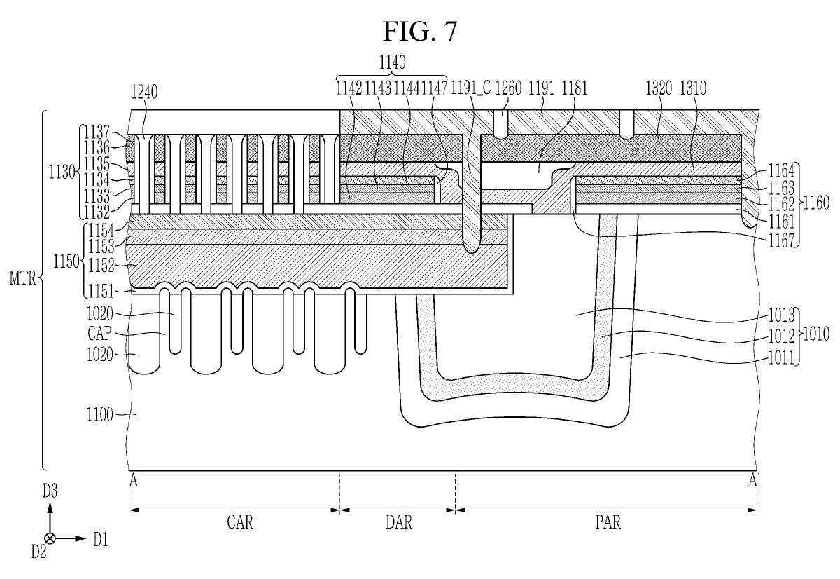

FIG. 7 is a cross-sectional view of a semiconductor device according to some implementations, corresponding to FIG. 4. For the convenience of the description, the description will focus on points that differ from those described using FIGS. 1 to 6 will be highlighted.

Referring to FIG. 7, the cell gate structure 1150 may further include a cell gate hydrogen diffusion blocking layer 1154 on the cell gate capping layer 1153. The cell gate hydrogen diffusion blocking layer 1154 may cover the cell gate capping layer 1153. The cell gate hydrogen diffusion blocking layer 1154 may be positioned beneath the bit line structures 1130 and may be positioned between the cell gate capping layer 1153 and the bit line structures 1130.

For example, the cell gate hydrogen diffusion blocking layer 1154 may have a lower hydrogen diffusivity than the cell gate capping layer 1153. The cell gate hydrogen diffusion blocking layer 1154 may include silicon nitride, which has a low hydrogen diffusivity. The cell gate hydrogen diffusion blocking layer 1154 may have a lower hydrogen concentration than the cell gate capping layer 1153. In other words, it may not be used a hydrogen source such as SiH₄ or NH₃ when forming the cell gate hydrogen diffusion blocking layer 1154. The cell gate hydrogen diffusion blocking layer 1154 may include 1 at% or less of hydrogen based on a total of the cell gate hydrogen diffusion blocking 1154, or hydrogen may not be included. The cell gate hydrogen diffusion blocking layer 1154 can prevent hydrogen from diffusing upwards from the cell gate capping layer 1153, such as into the data storage pattern DSP or the upper wiring structure 1170.

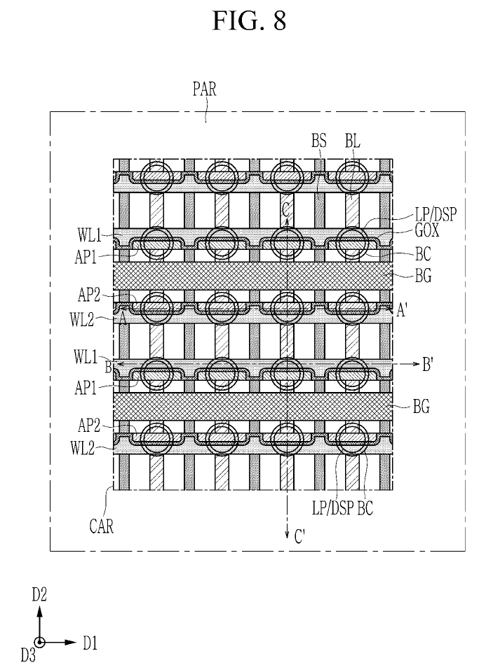

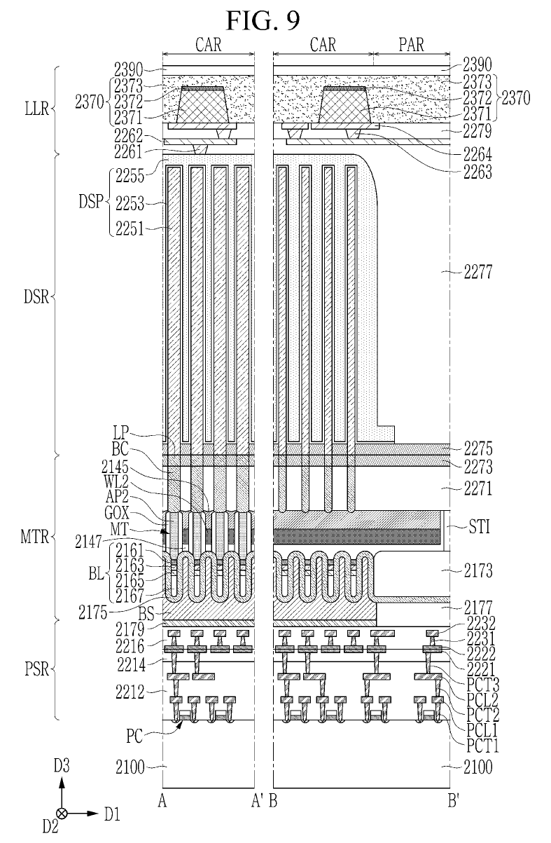

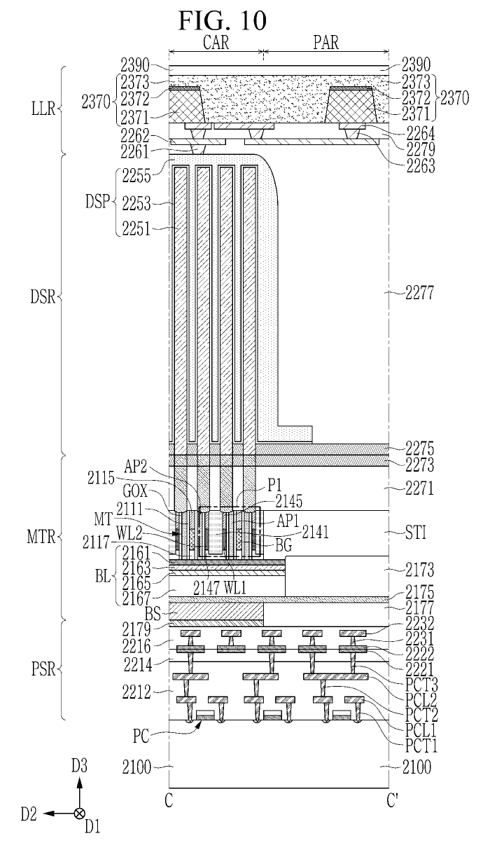

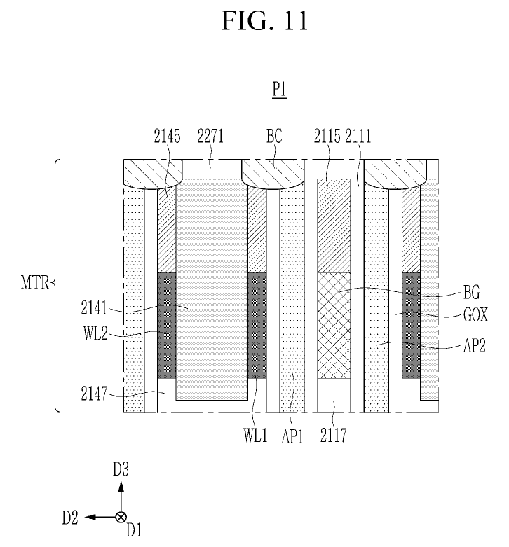

FIG. 8 is a plan view of a semiconductor device according to some implementations. FIG. 9 is a cross-sectional view taken along lines A-A' and B-B' of FIG. 8. FIG. 10 is a cross-sectional view taken along line C-C' of FIG. 8. FIG. 11 is an enlarged view of a P1 region of FIG. 10.

A semiconductor device according to some implementations may include multiple memory cells including a vertical channel transistor (VCT). However, this is illustrative, and the semiconductor device according to some implementations is not limited to this and may be variously changed.

Referring to FIGS. 8 to 11, a semiconductor device according to some implementations may include a substrate 2100, a peripheral circuit structure PSR positioned on the substrate 2100, a memory transistor region MTR positioned on the peripheral circuit structure PSR, a data storage pattern region DSR positioned on the memory transistor region MTR, and a wiring region LLR positioned on the data storage pattern region DSR. The memory transistor region MTR may be a region including a plurality of memory transistors. The data storage pattern region DSR may be a region including a plurality of data storage patterns. The wiring region LLR may be a region including a plurality of wirings connected to a plurality of transistors.

The substrate 2100 may include a cell region CAR and a peripheral region PAR defined around the cell region CAR. For example, the peripheral region PAR may be positioned adjacent to the cell region CAR and may surround the cell region CAR. However, the arrangement relationship between the cell region CAR and the peripheral region PAR is not limited to this and may be variously changed.

In the cell region CAR, multiple memory cell structures including memory transistors MT and data storage patterns DSP are positioned, and in the peripheral region PAR, multiple contacts and contact wirings connected to the components positioned in the cell region CAR may be positioned.

A memory cell structure may include a single memory transistor MT and a single data storage pattern DSP. Two distinguishable states may be determined depending on the presence or absence of charges stored in the data storage pattern DSP, and the data storage pattern DSP may function as a memory element.

The gate electrode of the memory transistor MT may be connected to the first and second word lines WL1, WL2, the first source/drain electrode of the memory transistor MT may be connected to one terminal of the data storage pattern DSP, and the second source/drain electrode of the memory transistor MT may be connected to a bit line BL.

The substrate 2100 may be a silicon substrate, or may include other materials, for example, silicon germanium, indium antimonide, lead telluride compounds, indium arsenide, indium phosphide, gallium arsenide or gallium antimonide, but is not limited thereto, and the materials included in the substrate 2100 may be variously changed.

In some implementations, the peripheral circuit structure PSR and memory cell structure positioned on the substrate 2100 may be arranged to overlap in a vertical direction. For example, the peripheral circuit structure PSR and memory cell structure may be sequentially stacked on the substrate 2100. That is, the memory cell structure may be positioned on the peripheral circuit structure PSR. However, it is not limited to this, and the stacking relationship between the memory cell structure and the peripheral circuit structure PSR may be variously changed. For example, the memory cell structure may be positioned adjacent to the peripheral circuit structure PSR in a horizontal direction. As another example, the memory cell structure can be positioned underneath the peripheral circuit structure PSR and overlap in a vertical direction. In the following, a structure in which the memory cell structure is positioned on the peripheral circuit structure PSR is assumed for explanation.

The peripheral circuit structure PSR may be positioned on the substrate 2100. The peripheral circuit structure PSR may be positioned between the substrate 2100 and the memory cell structure.

The peripheral circuit structure PSR may be positioned across the cell region CAR and the peripheral region PAR of the substrate 2100. That is, a portion of the peripheral circuit structure PSR may be positioned in the cell region CAR of the substrate 2100, and the remaining portion may be positioned in the peripheral region PAR.

In some implementations, a peripheral circuit structure PSR may include a core region and a peripheral region. The core region and the peripheral region may collectively be referred to as a logic region or a peripheral circuit region.

The core area may include a core bank, and the core bank may include core circuits such as a word line driver, a sense amplifier, a row decoder, a column decoder, and a read/write (R/W) circuit.

The peripheral region may include peripheral circuits such as a timing register, an address register, a data input register, a data output register, and data input/output terminals.

The peripheral circuit structure PSR may include peripheral circuits PC for driving components positioned in the memory cell structure. For example, the peripheral circuit PC may include the core circuit and/or a peripheral circuit.

The peripheral circuit structure PSR may include a peripheral circuit PC, first to third peripheral circuit contacts PCT1, PCT2, PCT3, first and second peripheral circuit wirings PCL1, PCL2, a peripheral circuit insulation layer 2212, a first bonding insulation layer 2214, and first bonding pads 2221.

A peripheral circuit PC may be positioned on a substrate 2100. The peripheral circuit PC may be, for example, a sensing transistor, a transmission transistor, or a drive transistor. However, the type of transistor in the peripheral circuit PC may be variously changed depending on the design of the semiconductor device.

The peripheral circuit insulating layer 2212 may cover the peripheral circuit PC. In other words, the peripheral circuit insulating layer 2212 may cover the side and upper surfaces of the peripheral circuit PC. The peripheral circuit insulating layer 2212 may include an insulating material. For example, the peripheral circuit insulating layer 2212 may include silicon oxide, silicon nitride, silicon oxynitride, and/or a low dielectric constant constant material, but is not limited thereto.

The first to third peripheral circuit contacts PCT1, PCT2, PCT3 and the first and second peripheral circuit wirings PCL1, PCL2 may be positioned within the peripheral circuit insulating layer 2212.

The first peripheral circuit wiring PCL1 may be connected to the peripheral circuit PC through the first peripheral circuit contact PCT1. The first peripheral circuit wiring PCL1 may be connected to the source/drain region positioned on at least one side of the peripheral circuit PC through the first peripheral circuit contact PCT1. The first peripheral circuit wiring PCL1 and the second peripheral circuit wiring PCL2 may be connected by the second peripheral circuit contact PCT2.

For example, the peripheral circuit insulating layer 2212 has been shown as a single layer, but is not limited thereto, and the peripheral circuit insulating layer 2212 may be formed as a multilayer including the same material and/or different materials.

In cases where the peripheral circuit insulating layer 2212 is made of multiple layers, at least some of the first peripheral circuit contact PCT1, the second peripheral circuit contact PCT2, the third peripheral circuit contact PCT3, the first peripheral circuit wiring PCL1, the second peripheral circuit wiring PCL2, and the third peripheral circuit wiring PCL3 may be positioned in the same or different layers.

The first bonding insulating layer 2214 may be positioned on the peripheral circuit insulating layer 2212. The first bonding insulating layer 2214 may include an insulating material. For example, the first bonding insulating layer 2214 may include silicon carbide, but it is not limited thereto. In another example, the first bonding insulating layer 2214 may also include silicon oxide, silicon nitride oxide, silicon oxycarbonitride, or silicon nitride.

The third peripheral circuit contact PCT3 may be positioned within the peripheral circuit insulating layer 2212 and the first bonding insulating layer 2214. That is, a part of the third peripheral circuit contact PCT3 may be positioned in the peripheral circuit insulating layer 2212, and the remaining part may be positioned within the first bonding insulating layer 2214.

The first bonding pads 2221 may be positioned within the first bonding insulating layer 2214. The first bonding insulating layer 2214 may surround the first bonding pads 2221. The first bonding insulating layer 2214 may surround the side and bottom surfaces of the first bonding pad 2221. The upper surface of the first bonding insulating layer 2214 is positioned substantially at the same level as the upper surfaces of the first bonding pads 2221, and the first bonding insulating layer 2214 may expose the upper surfaces of the first bonding pads 2221. The first bonding pad 2221 may be connected to the second peripheral circuit wiring PCL2 through the third peripheral circuit contact PCT3.

For example, the peripheral circuit structure PSR and the memory cell structure may be semiconductor devices joined using a Cu-to-Cu (C2C) wafer bonding method. For example, the peripheral circuit structure PSR and the memory cell structure may be semiconductor devices joined using a Hybrid Copper Bonding (HCB) method. However, the bonding method of peripheral circuit structure PSR and memory cell structure is not limited to this and may be variously changed.

In some implementations, the memory cell structure and the peripheral circuit structure PSR may be connected by a single through via using a direct bonding method. For example, the memory cell structure and the peripheral circuit structure PSR may be connected to a single through via that extends from the peripheral circuit structure PSR to the memory cell structure.

For example, the memory cell structure may include a second bonding insulating layer 2216 that contacts the first bonding insulating layer 2214 of the peripheral circuit structure PSR. The second bonding insulating layer 2216 may include the same material as the first bonding insulating layer 2214 positioned in the peripheral circuit structure PSR and may be positioned on the first bonding insulating layer 2214.

The second bonding pads 2222 may position within the second bonding insulating layer 2216 positioned in the memory cell structure. The second bonding insulating layer 2216 may surround the second bonding pads 2222. The second bonding insulating layer 2216 may surround the sides and uppers surfaces of the second bonding pad 2222. The bottom of the second bonding insulating layer 2216 is substantially same level with the bottom of the second bonding pads 2222, and the second bonding insulating layer 2216 may expose the bottoms of multiple second bonding pads 2222.

The second bonding pads 2222 positioned within the second bonding insulating layer 2216 may be directly in contact with the first bonding pads 2221 positioned within the first bonding insulating layer 2214, thereby constituting a metal bond. The upper surface of the first bonding pads 2221 and the lower surface of the second bonding pads 2222 may come into contact. The first bonding pads 2221 and the second bonding pads 2222 are positioned at the boundary area between the peripheral circuit structure PSR and the memory cell structure and may come into contact with each other.

Additionally, a first bonding insulating layer 2214 positioned in the peripheral circuit structure PSR and a second bonding insulating layer 2216 positioned in the memory cell structure may contact each other to constitute a bonding insulating layer.

Therefore, one surface of the memory cell structure and one surface of the peripheral circuit structure PSR may be bonded. In other words, the first bonding pads 2221 positioned in the peripheral circuit structure PSR and the first bonding insulating layer 2214 constitute one surface or a junction surface of the peripheral circuit structure PSR, and the second bonding pads 2222 positioned in the memory cell structure and the second bonding insulating layer 2216 may constitute one surface or a joining surface of the memory cell structure.

The first bonding pads 2221 of the peripheral circuit structure PSR and the second bonding pads 2222 of the memory cell structure may be coupled together, providing an electrical connection path between the peripheral circuit structure PSR and the memory cell structure. For example, cell connection wirings 2232 connected to the components included in the memory cell structure may be connected to the peripheral circuit PC and/or the first and second peripheral circuit wirings PCL1, PCL2 included in the peripheral circuit structure PSR via the first bonding pad 2221 and the second bonding pad 2222.

The memory cell structure may include a cell connection wiring contact 2231 and cell connection wiring 2232, both positioned within the second bonding insulating layer 2216. The cell connection wiring 2232 is connected to components positioned at the memory cell structure, and the cell connection wiring contact 2231 may connect the second bonding pad 2222 and the cell connection wiring 2232. For example, the cell connection wiring 2232 may be connected to memory cells positioned at the memory cell structure, which include a memory transistor MT and the data storage patterns DSP, as well as to first and second word lines WL1, WL2 and a bit line BL connected to them.

The first to third peripheral circuit contacts PCT1, PCT2, PCT3 positioned in the peripheral circuit structure PSR, and the first and second peripheral circuit wirings PCL1, PCL2, as well as a cell connection wiring contact 2231 and a cell connection wiring 2232 each positioned in a memory cell structure, may each include a conductive material. For example, they may include aluminum (Al), tungsten (W), titanium (Ti), copper (Cu), or tantalum (Ta), but it is not limited thereto.

The memory cell structure may include a bit line BL, a first word line WL1 and a second word line WL2 disposed on the bit line BL, a first active pattern AP1 and a second active pattern AP2 disposed on the bit line BL and positioned between the first word line WL1 and the second word line WL2, and a gate hydrogen diffusion pattern 2145 positioned on the first word line WL1 and the second word line WL2.

The bit lines BL may be parallel to each other and extend in a second direction D2 intersecting with a first direction D1 that is parallel to the upper surface of the substrate 2100. The bit lines BL may be spaced apart from each other on the substrate 2100 in the first direction D1.

The bit line BL may include a sequentially stacked polysilicon layer 2161, a first metal layer 2163, a second metal layer 2165, and a bit line capping layer 2167.

The polysilicon layer 2161 may include doped polysilicon, and the first metal layer 2163 and the second metal layer 2165 may include conductive materials. For example, the first metal layer 2163 may include conductive metal nitrides for example, titanium nitride, or tantalum nitride, etc., and the second metal layer 2165 may include metals for example, tungsten, titanium, or tantalum, etc.

Moreover, at least one of the first metal layer 2163 and the second metal layer 2165 may include a metal silicide such as titanium silicide, cobalt silicide, or nickel silicide. However, the materials included in the first metal layer 2163 and the second metal layer 2165 are not limited thereto and may be variously changed.

The bit line capping layer 2167 may include an insulating material such as silicon nitride or silicon oxynitride.

In some implementations, the bit lines BL may include 2-dimensional and 3-dimensional materials, for example, the bit lines BL may include one of a carbon-based 2-dimensional material such as graphene, a 3-dimensional material such as a carbon nanotube, or a combination thereof.

The bit lines BL may be positioned adjacent to the peripheral circuit structure PSR. As the bit lines BL are positioned adjacent to the peripheral circuit structure PSR, the electrical connection path between the bit lines BL and peripheral circuits PC may be reduced.

In some implementations, the semiconductor device may further include a bit line shielding pattern BS and a spacer insulating layer 2175 positioned between the peripheral circuit structure PSR and the memory cell structure.

The bit line shielding pattern BS may be positioned between the peripheral circuit structure PSR and the bit line BL. Further, the bit line shielding pattern BS may be positioned between adjacent bit lines BL and may extend in a second direction D2. In other words, the bit line shielding pattern BS may be arraged alternately with the bit lines BL and spaced apart in the first direction D1.

The spacer insulating layer 2175 may be conformally positioned on the bit lines BL. The spacer insulating layer 2175 may cover the opposing sides and the upper surface of the bit lines BL. The spacer insulating layer 2175 may define a gap region between the bit lines BL. The gap region of the spacer insulating layer 2175 may extend in the second direction D2 parallel to the bit lines BL.

The bit line shielding pattern BS may include a conductive material. For example, the bit line shielding pattern BS may include a metal material such as tungsten (W), titanium (Ti), nickel (Ni), or cobalt (Co). In another example, the bit line shielding pattern BS may include a two-dimensional conductive material like graphene, but it is not limited thereto.

The spacer insulating layer 2175 may include an insulating material. For example, it may include silicon oxide, silicon nitride, silicon oxynitride, and/or a low dielectric constant material.

The bit line shielding pattern BS may be positioned on the spacer insulating layer 2175. The bit line shielding pattern BS may be positioned within the gap region of the spacer insulating layer 2175.

The bit line shielding pattern BS may include line portions positioned between neighboring bit lines BL, and a connection portion commonly connecting the line portions.

The line portion of a bit line shield pattern BS may be positioned between bit lines BL and may be positioned within a plurality of gap regions defined by a spacer insulating layer 2175. Accordingly, the sides of the line portions of the bit line shielding pattern BS and the bit lines BL may be separated, with the spacer insulating layer 2175 positioned in between.

The connection part of the bit line shielding pattern BS is connected to the line portions and may be integrated with the line portions. The connection portion of the bit line shielding pattern BS is positioned on the line portions, and may connect the line portions positioned between the adjacent bit lines BL. However, it is not limited thereto, and in some implementations, the line portions and connection portion of the bit line shielding pattern BS may be composed of separate components.

In some implementations, the connection portion of the bit line shielding pattern BS may extend from the cell region CAR to the peripheral region PAR. Accordingly, the end portion of the connection portion of the bit line shielding pattern BS may be positioned in the peripheral region PAR. The connection portion of the bit line shielding pattern BS positioned in the peripheral region PAR may be connected to the bit line shielding contact.

The semiconductor device may further include a bit line shielding capping layer 2179, a first cell insulating layer 2177 positioned between the spacer insulating layer 2175 and the second bonding insulating layer 2216, a second cell insulating layer 2173 positioned on the spacer insulating layer 2175, and a device isolation layer STI positioned on the second cell insulating layer 2173.

The bit line shielding capping layer 2179 may be positioned between the bit line shielding pattern BS and the second bonding insulating layer 2216, and may cover the bit line shielding pattern BS.

The first cell insulating layer 2177 may be positioned on the second bonding insulating layer 2216. The upper surface of the first cell insulating layer 2177 may be in contact with the spacer insulating layer 2175, and the side of the first cell insulating layer 2177 may come into contact with the ends of the bit line shielding pattern BS and the bit line shielding capping layer 2179.

The second cell insulating layer 2173 may be positioned on the spacer insulating layer 2175.

The second cell insulation layer 2173 may be in contact with the end of the bit line BL and may cover the end of the bit line BL. However, this is illustrative, and the second cell insulation layer 2173 may be spaced apart from the end of the bit line BL.

The device isolation layer STI may be positioned on the second cell insulating layer 2173. A portion of the device isolation layer STI may overlap with the bit line BL in the third direction D3.

The bit line shielding capping layer 2179, the first cell insulating layer 2177, the second cell insulating layer 2173, and the device isolation layer STI may include silicon oxide, silicon nitride, silicon oxynitride, and/or a low dielectric constant material. For example, the bit line shielding capping layer 2179 may include silicon nitride, and the first cell insulating layer 2177, the second cell insulating layer 2173, and the device isolation layer STI may include silicon oxide. However, these are merely examples, and the materials included in each of the bit line shielding capping layer 2179, the first cell insulating layer 2177, the second cell insulating layer 2173, and the device isolation layer STI may be variously changed.

The first and second active patterns AP1, AP2 are positioned between the first and second word lines WL1, WL2. For example, the first active pattern AP1 may be arranged on the side of the first word line WL1, and the second active pattern AP2 may be arranged on the side of the second word line WL2. In other words, the first active pattern AP1 may be arranged closer to the first word line WL1 than the second active pattern AP2, and the second active pattern AP2 may be arranged closer to the second word line WL2 than the first active pattern AP1. The first and second active patterns AP1, AP2 may be alternately positioned along the second direction D2 on the bit line BL. For example, the first and second active patterns AP1, AP2 may be arranged two-dimensionally on a plane along the first direction D1 and second direction D2.

For example, the first active pattern AP1 and the second active pattern AP2 may each be made of single-crystal semiconductor materials. For example, the first active pattern AP1 and the second active pattern AP2 may each consist of single-crystal silicon. However, this is not limited and the materials included in the first and second active patterns AP1, AP2 may be variously changed. For example, the first and second active patterns AP1, AP2 may include polycrystalline semiconductor, oxide semiconductor, two-dimensional material, or a combination thereof. For example, the polycrystalline semiconductor may be polysilicon. In another example, the oxide semiconductor may be Indium Gallium Zinc Oxide (IGZO). In yet another example, the two-dimensional material may be MoS₂, WS₂, MoSe₂, or WSe₂.

In some implementations, a semiconductor device may include back gate electrodes BG that extend in a direction different from the bit line BL between the first active pattern AP1 and the second active pattern AP2.

The back gate electrode BG is positioned between the first active pattern AP1 and the second active pattern AP2 which are adjacent to each other in the second direction D2, and may extend along the first direction D1 crossing the bit line BL. That is, the back gate electrode BG may extend in a direction different from the extension direction of the bit line BL.

The back gate electrode BG may be positioned on the bit line BL and the bit line shield pattern BS. The first active pattern AP1 may be positioned on one side of the back gate electrode BG in a second direction D2, and the second active pattern AP2 may be positioned on the other side of the back gate electrode BG in the second direction D2.

The back gate electrode BG may be positioned between a pair of adjacent first word line WL1 and second word line WL2 in the second direction D2. For example, the first active pattern AP1 may be positioned between the first word line WL1 and the back gate electrode BG, and the second active pattern AP2 may be positioned between the second word line WL2 and the back gate electrode BG. However, this is exemplary, and the arrangement relationship between the first and second active patterns AP1, AP2, the first and second word lines WL1, WL2, and the back gate electrode BG is not limited thereto and may be variously changed.

The back gate electrode BG may include a conductive material. For example, the back gate electrode BG may include doped polysilicon, conductive metal nitrides, conductive metal silicon nitrides, metal carbonitrides, conductive metal silicides, conductive metal oxides, 2-dimensional materials, metals, or combinations thereof. However, this is exemplary, and the conductive material may be variously changed.

The back gate electrode BG may be applied with a negative voltage during the operation of the semiconductor device, thereby increasing the threshold voltage of the vertical channel transistor. That is, as the vertical channel transistor is miniaturized, it may prevent the decrease in threshold voltage and the deterioration of leak current characteristics.

The semiconductor device may further include a first back gate insulation pattern 2111 and a second back gate insulation pattern 2117.

The first back gate insulating pattern 2111 and the second back gate insulating pattern 2117 may be positioned between the first and second active patterns AP1, AP2 that are adjacent to each other in the second direction D2. The first back gate insulating pattern 2111 and the second back gate insulating pattern 2117 may extend in parallel with the back gate electrodes BG in the first direction D1.

The first back gate insulating pattern 2111 may contact the first and second active patterns AP1, AP2. The first back gate insulating pattern 2111 may extend in the third direction D3 along each side of the first and second active patterns AP1, AP2 facing each other in the second direction D2.

The first back gate insulating pattern 2111 may extend along both sides of the back gate electrode BG, and the second back gate insulating pattern 2117 may be positioned between a lower surface of the back gate electrode BG and the bit line BL.

The first back gate insulating pattern 2111 and the second back gate insulating pattern 2117 may include insulating material. The first back gate insulating pattern 2111 and the second back gate insulating pattern 2117 may each include silicon oxide, silicon oxynitride, silicon nitride, or combination thereof. However, the material included in the first back gate insulating pattern 2111 and the second back gate insulating pattern 2117 is not limited thereto, and may be variously changed.

The first and second word lines WL1, WL2 may be positioned on the bit line BL and the bit line shield pattern BS. The first and second word lines WL1, WL2 may extend in the first direction D1 intersecting with the second direction D2, which is the extension direction of the bit line BL. The first word lines WL1 and the second word lines WL2 may be positioned spaced apart from each other in the second direction D2.

The first active pattern AP1 and the second active pattern AP2 may be positioned between the first word line WL1 and the second word line WL2 that are adjacent in the second direction D2.

The first word line WL1 and the second word line WL2 may overlap with the bit line BL and the bit line shielding pattern BS in the third direction D3. The first word line WL1 and the second word line WL2 may extend in the third direction D3 that intersects perpendicularly with the first direction D1 and second direction D2.

The first word line WL1 and the second word line WL2 may be positioned between the bit line BL and a gate hydrogen diffusion pattern 2145 to be described later and may be extended in a third direction D3.

For example, the first and second word lines WL1, WL2 are illustrated as having a rectangular shape in cross-section, but the cross-sectional shapes of the first and second word lines WL1, WL2 are not limited thereto, and may be variously changed. For example, each of the first and second word lines WL1, WL2 may have an 'L' shape in cross-section.

The first and second word lines WL1, WL2 may include a conductive material. For example, the first and second word lines WL1, WL2 may include doped polysilicon, conductive metal nitrides, conductive metal silicon nitrides, metal carbonitrides, conductive metal silicides, conductive metal oxides, two-dimensional materials, metals, or a combination thereof. However, the conductive material is not limited thereto.

The semiconductor device may further include a gate insulating pattern GOX positioned on the sides of the first and second word lines WL1, WL2, a gate separating pattern 2141 positioned between the first and second word lines WL1, WL2, and a gate capping pattern 2147 positioned on lower surfaces of the first and second word lines WL1, WL2.

The gate insulating pattern GOX may be in contact with the first and second active patterns AP1, AP2. The gate insulating pattern GOX may extend in the third direction D3 along the sides of the first and second active patterns AP1, AP2 facing each other in the second direction D2.

The gate isolation pattern 2141 may be positioned between the first and second word lines WL1, WL2 spaced apart in the second direction D2. The gate isolation pattern 2141 may be positioned between the gate capping pattern 2147 and the subsequently described contact interlayer insulating layer 2271.

The gate isolation pattern 2141 may contact the first and second word lines WL1, WL2. The first and second word lines WL1, WL2 may be separated and insulated by the gate isolation pattern 2141. The gate isolation pattern 2141 may extend in the third direction D3 between the first and second word lines WL1, WL2.

The lower surface of the gate separation pattern 2141 may be positioned at a lower level than the lower surfaces of the first and second word lines WL1, WL2, and the upper surface may be positioned at a higher level than the upper surfaces of the first and second word lines WL1, WL2.

The gate capping pattern 2147 may be positioned underneath the first and second word lines WL1, WL2. The gate capping pattern 2147 may cover the lower surfaces of the first and second word lines WL1, WL2.

The lower surface and the adjacent side of the gate isolation pattern 2141 may be covered by the gate capping pattern 2147, and the upper surface may be covered by the contact interlayer insulating layer 2271.

The gate insulating pattern GOX may include silicon oxide, silicon oxynitride, a high dielectric material having a higher dielectric constant than silicon oxide, or a combination thereof. For example, the high dielectric material may include HfO₂, HfSiO, HfSiON, HfTaO, HfTiO, HfZrO, ZrO₂, Al₂O₃, or a combination thereof, but is not limited thereto.

The gate isolation pattern 2141 and the gate capping pattern 2147 may include silicon oxide, silicon nitride, or a combination thereof. For example, the gate isolation pattern 2141 may include silicon oxide, and the gate capping pattern 2147 may include silicon nitride, but is not limited thereto.

The gate hydrogen diffusion patterns 2145 may be positioned on the first and second word lines WL1, WL2. In other words, the gate hydrogen diffusion patterns 2145 may be positioned to overlap with the first and second word lines WL1, WL2 in the third direction D3. The gate hydrogen diffusion patterns 2145 may be positioned between the first and second word lines WL1, WL2 and the data storage pattern DSP. The gate hydrogen diffusion patterns 2145 may be positioned between an upper surface of the first and second word lines WL1, WL2 and a lower surface of a later-described storage contact BC.

The gate hydrogen diffusion pattern 2145 may include insulating material and hydrogen. In other words, the gate hydrogen diffusion pattern 2145 may be a hydrogen-rich (H-rich) insulating layer. The gate hydrogen diffusion pattern 2145 can provide hydrogen to the boundaries between the peripheral structures, for example, the gate insulating pattern GOX and the first and second active patterns AP1, AP2, through annealing, and thus may passivate dangling bonds with hydrogen. The gate hydrogen diffusion pattern 2145 may still include hydrogen even after supplying hydrogen to the boundaries between the gate insulating pattern GOX and the first and second active patterns AP1, AP2.

For example, an annealing process for diffusing hydrogen may be performed at a pressure of 10 Torr to 40 Torr, for example, 20 Torr to 30 Torr, for 15 minutes to 60 minutes, for example, 30 minutes to 45 minutes, at a temperature of 400 °C to 475 °C, for example 375 °C to 400 °C. The annealing process may be performed at temperatures below the temperature range inducing crystallization of the materials of the first and second active patterns AP1, AP2 for example, below 600°C.

The insulating material of the gate hydrogen diffusion pattern 2145 may include silicon nitride, silicon oxide, tetraethylortho silicate (TEOS), or a combination thereof. For example, by depositing SiH₄ and O₂ as source materials, a hydrogen-rich gate hydrogen diffusion pattern 2145 including silicon oxide and hydrogen may be formed. Additionally, by depositing SiH₄ and NH₃ as source materials, a hydrogen-rich gate hydrogen diffusion pattern 2145 including silicon nitride and hydrogen can be formed. In this case, the deposition may use methods such as Atomic Pressure CVD (APCVD), Low Pressure CVD (LPCVD), Plasma Enhanced CVD (PECVD), or High Density Plasma CVD (HDPCVD). Alternatively, after depositing silicon oxide or silicon nitride, hydrogen may be plasma-doped into the silicon oxide or silicon nitride to form a hydrogen-rich gate hydrogen diffusion pattern 2145.

For example, the gate hydrogen diffusion pattern 2145 may be a TEOS layer including tetraethylortho silicate (TEOS), and the gate hydrogen diffusion pattern 2145 may be an HDP layer including high density plasma CVD (HDP CVD) dielectric material.

The gate hydrogen diffusion pattern 2145 may include hydrogen, deuterium, tritium, or a combination thereof. The hydrogen may be a hydrogen atom or a hydrogen molecule. Since deuterium or tritium is heavier than hydrogen, when the gate hydrogen diffusion pattern 2145 includes deuterium or tritium, it may reduce the loss of deuterium or tritium into the air compared to when it includes hydrogen. For example, the gate hydrogen diffusion pattern 2145 may include 90 % or more of hydrogen with respect to the sum of hydrogen, deuterium, and tritium.

For example, the gate hydrogen diffusion pattern 2145 may include hydrogen in an amount of greater than 0 at% based on a total of gate hydrogen diffusion pattern 2145, for example, 1 at% or more, 2 at% or more, 3 at% or more, or 4 at% or more, and it may include hydrogen in an amount of 5 at% or less, for example, 4 at% or less, 3 at% or less, or 2 at% or less, and for example, it may include hydrogen in an amount of greater than 0 at% and less than or equal to 5 at%.

Furthermore, the ratio of the hydrogen intensity measured by the Secondary Ion Mass Spectroscopy (SIMS) of the gate hydrogen diffusion pattern 2145 to the hydrogen intensity measured by the SIMS of the first and second active patterns AP1, AP2 adjacent thereto may be 10 or more : 1, for example, 100 or more : 1, or 1000 or more : 1.

For example, when the gate insulating pattern GOX includes silicon dioxide (SiO₂), and the first and second active patterns AP1, AP2 include silicon (Si), dangling bonds existing at the interface between silicon dioxide (SiO₂) and silicon (Si) may be passivated with hydrogen.

For this purpose, as described later, the upper wiring structure 2370 may include an upper wiring hydrogen diffusion layer 2372 covering the upper wiring layer 2371 and including an insulating material and hydrogen. After forming the upper wiring hydrogen diffusion layer 2372 and then annealing, the hydrogen of the upper wiring hydrogen diffusion layer 2372 may be supplied to the first and second word lines WL1, WL2 through the data storage pattern DSP in the cell area CAR, and may diffuse up to the boundary between the gate insulation pattern GOX and the first and second active patterns AP1, AP2.

However, upon hydrogen diffusion from the upper wiring hydrogen diffusion layer 2372, due to the hydrogen diffusion path, reliability degradation may be induced in the upper wiring structure 2370 and the data storage pattern DSP. In addition, hydrogen from the upper wiring hydrogen diffusion layer 2372 may also diffuse into the peripheral circuit PC via the peripheral circuit contacts PCT1, PCT2, PCT3 and peripheral circuit wires PCL1, PCL2 in the peripheral region PAR, and due to the hydrogen diffusion path, reliability degradation may be induced in the peripheral circuit PC.

For example, in the upper wiring structure 2370, the hydrogen embrittlement of copper (Cu) wiring may degrade due to hydrogen diffusion, and moisture absorption vulnerability may occur due to degradation of interfacial adhesion. In the data storage pattern DSP, reliability may be degraded by the combination of hydrogen ions (H⁺) with oxygen vacancies within the dielectric layer 1253 due to hydrogen diffusion. In the peripheral circuit PC, Negative Bias Temperature Instability (NBTI) may be deteriorated due to residual hydrogen from hydrogen diffusion.

According to some implementations, the gate hydrogen diffusion pattern 2145 including an insulating material and hydrogen is positioned on the first and second word lines WL1, WL2. Accordingly, hydrogen may be diffused from the gate hydrogen diffusion pattern 2145 to the boundary between the gate insulating pattern GOX and the first and second active patterns AP1, AP2. By directly diffusing hydrogen from the gate hydrogen diffusion pattern 2145 to the boundary between the gate insulating pattern GOX and the first and second active patterns AP1, AP2, it is advantageous in terms of hydrogen supply dispersion, and the upper wiring structure 2370, the data storage pattern DSP, and the peripheral circuit PC may not experience reliability degradation due to the hydrogen diffusion path.

In some implementations, a semiconductor device may include a back gate hydrogen diffusion pattern 2115 positioned on the back gate electrode BG. The back gate hydrogen diffusion pattern 2115 may be positioned to overlap with the back gate electrode BG in a third direction D3. The back gate hydrogen diffusion pattern 2115 may extend along the third direction D3 on the back gate electrode BG. The back gate hydrogen diffusion pattern 2115 may be positioned between a first active pattern AP1 and a second active pattern AP2 that are adjacent to each other in a second direction D2.

The back gate hydrogen diffusion pattern 2115 may include insulating materials and hydrogen. In other words, the back gate hydrogen diffusion pattern 2115 may be a hydrogen-rich (H-rich) insulating layer. The back gate hydrogen diffusion pattern 2115 may supply hydrogen to the boundaries of surrounding structures, for example, the gate insulator pattern GOX and the first and second active patterns AP1, AP2 through annealing, and may passivate dangling bonds with hydrogen. The back gate hydrogen diffusion pattern 2115 may include hydrogen even after supplying hydrogen to the boundaries between the gate insulator pattern GOX and the first and second active patterns AP1, AP2.

The insulating material of the back gate hydrogen diffusion pattern 2115 may include silicon nitride, silicon oxide, tetraethylortho silicate (TEOS), or a combination thereof. For example, if deposited using SiH₄ and O₂ as raw materials, a hydrogen-rich back gate hydrogen diffusion pattern 2115 that includes silicon oxide and hydrogen may be formed. Furthermore, when SiH₄ and NH₃ are used as raw materials for deposition, a hydrogen-rich back gate hydrogen diffusion pattern 2115 that includes silicon nitride and hydrogen may be formed. In this case, deposition may use methods such as Atomic Pressure CVD (APCVD), Low Pressure CVD (LPCVD), Plasma Enhanced CVD (PECVD), or High Density Plasma CVD (HDPCVD). Alternatively, following the deposition of silicon oxide or silicon nitride, a hydrogen-rich back gate hydrogen diffusion pattern 2115 may be formed by plasma doping hydrogen into the silicon oxide or silicon nitride.

For example, the back gate hydrogen diffusion pattern 2115 may be a TEOS layer including tetraethylortho silicate (TEOS), and the back gate hydrogen diffusion pattern 2115 may be an HDP layer including a high-density plasma CVD (HDP CVD) dielectric material.

The back gate hydrogen diffusion pattern 2115 may include hydrogen, deuterium, tritium, or a combination thereof. Hydrogen may be a hydrogen atom or a hydrogen molecule. Since deuterium or tritium is heavier than hydrogen, when the back gate hydrogen diffusion pattern 2115 includes deuterium or tritium, it may reduce the loss of deuterium or tritium into the air compared to when it includes hydrogen. For example, the back gate hydrogen diffusion pattern 2115 may include 90 % or more of hydrogen with respect to the sum of hydrogen, deuterium, and tritium.

For example, the back gate hydrogen diffusion pattern 2115 may include hydrogen in an amount of greater than 0 at% based on a total of the back gate hydrogen diffusion pattern 2115, for example, 1 at% or more, 2 at% or more, 3 at% or more, or 4 at% or more, it may include hydrogen in an amount of 5 at% or less, for example, 4 at% or less, 3 at% or less, or 2 at% or less, and for example, it may include hydrogen in an amount of greater than 0 at% and less than or equal to 5 at%.

Additionally, the ratio of the hydrogen intensity measured by the secondary ion mass spectroscopy (SIMS) of the back gate hydrogen diffusion pattern 2115 to the hydrogen intensity measured by the secondary ion mass spectroscopy (SIMS) of the first and second active patterns AP1, AP2 adjacent to it may be 10 or more : 1, for example, 100 or more : 1, or 1000 or more : 1.

The semiconductor device may further include a contact interlayer insulating layer 2271, a pad separation insulating layer 2273, and a contact etch stop layer 2275, sequentially stacked on the first and second active patterns AP1, AP2.

The contact interlayer insulating layer 2271 may be positioned on the first and second active patterns AP1, AP2. The contact interlayer insulating layer 2271 may cover the first back gate insulating pattern 2111, the gate hydrogen diffusion pattern 2145, the back gate hydrogen diffusion pattern 2115, the gate isolation pattern 2141, and the device isolation layer STI.

The interlayer insulating layer 2271, the pad separation insulating layer 2273, and the contact etch stop layer 2275 may include silicon oxide, silicon nitride, or a combination thereof. For example, the interlayer insulating layer 2271 may include silicon oxide, and the pad separation insulating layer 2273 and the etch stop layer 2275 may include silicon nitride but these layers are not limited thereto.

In the cell region CAR of the memory cell structure, a storage contact BC, landing pad LP, and a data storage pattern DSP may be sequentially stacked.

The semiconductor device may include the storage contacts BC.

The storage contacts BC may extend through the contact interlayer insulating layer 2271. The storage contacts BC may respectively connect to the first and second active patterns AP1, AP2. Adjacent storage contacts BC may be separated and insulated from each other by the contact interlayer insulating layer 2271.

The storage contacts BC may be arranged in a matrix pattern along a first direction D1 and a second direction D2 on a plane. In FIG. 8, the storage contacts BC are illustrated as having a circular shape on the plane, but this disclosure is not limited thereto, and the storage contacts BC may have various shapes on the plane, such as elliptical, rectangular, square, rhombic, or hexagonal.

The storage contact BC may include a conductive material. For example, the conductive material may include impurity-doped polysilicon, conductive metal nitrides, conductive metal silicon nitrides, metal carbonitrides, conductive metal silicides, conductive metal oxides, 2D materials, metals, or a combination thereof. For example, the storage contact BC may include n-type impurity-doped polysilicon. However, the material included in the storage contact BC is not limited to this and may be variously changed.

The semiconductor device may include landing pads LP. Each of the landing pads LPs may be positioned on the respective storage contacts BC.

The landing pads LP may be arrayed in a matrix shape along a first direction D1 and a second direction D2 on a plane. In FIG. 8, the landing pad LP is shown to have a circular shape on the plane, however, it is not limited to this shape, and the landing pad LP may have various shapes such as an ellipse, rectangle, square, rhombus, or hexagon on the plane.

The pad separation insulating layers 2273 may be positioned between the landing pads LP. The upper surface of the landing pad LP may be substantially at the same level as the upper surface of the pad separation insulating layer 2273.

The landing pad LP may include a conductive material. The conductive material may include, for example, doped polysilicon, conductive metal nitrides, conductive metal silicon nitrides, metal carbonitrides, conductive metal silicides, conductive metal oxides, two-dimensional materials, metals, or a combination thereof.

The semiconductor device may include the data storage patterns DSP. The data storage patterns DSP may be arranged in a matrix pattern along the first direction D1 and the second direction D2 as shown in FIG. 8.

The data storage patterns DSP may each be positioned on the landing pads LP. The data storage patterns DSP may be fully or partially overlapped with each of the landing pads LP in the third direction D3. The data storage patterns DSP may each be connected to the first and second active patterns AP1, AP2.

For example, the data storage pattern DSP may include a capacitor including a first electrode 2251, a second electrode 2255, and a dielectric layer 2253 positioned between the first electrode 2251 and the second electrode 2255.

The first electrode 2251 may be connected to the landing pad LP through the contact etch stop layer 2275. The first electrode 2251 may be extended in a third direction D3 on the landing pad LP.

The first electrode 2251 may include a metal, a conductive metal nitride, or a combination thereof. For example, the first electrode 2251 may include TiN, Ru, TaN, WN, Pt, Ir, or a combination thereof. However, the material included in the first electrode 2251 is not limited thereto and may be variously changed.

The dielectric layer 2253 may extend conformally along the upper surface and side profile of the first electrode 2251. That is, the dielectric layer 2253 may cover the side surface and upper surface of the first electrode 2251. A portion of the dielectric layer 2253 may be positioned on the upper surface of the contact etch stop layer 2275. That is, a portion of the dielectric layer 2253 may be positioned between the contact etch stop layer 2275 and the second electrode 2255.

The dielectric layer 2253 may include tantalum oxide (Ta₂O₅), aluminum oxide (Al₂O₃), titanium oxide (TiO₂), or a combination thereof. However, it is not limited thereto, and the material included in the dielectric layer 2253 may be variously changed.

The second electrode 2255 may be positioned on the dielectric layer 2253. The second electrode 2255 may entirely cover the first electrode 2251. That is, the second electrode 2255 may cover the upper surface and side surface of the first electrode 2251.

The second electrode 2255 may include a metallic material such as W, Ti, Ru, or SiGe. For example, the second electrode 2255 may include tungsten (W). However, the material included in the second electrode 2255 is not limited to thereto and may be variously changed. For example, the second electrode 2255 may include conductive metal nitrides, metal silicides or a combination thereof.

The semiconductor device may further include a third cell insulating layer 2277 and a fourth cell insulating layer 2279 sequentially stacked on the contact etch stop layer 2275.

Furthermore, the semiconductor device may further include a first cell wiring contact 2261 and a first cell wiring 2262, positioned within the third cell insulating layer 2277, and a second cell wiring contact 2263 and a second cell wiring 2264, positioned within the fourth cell insulating layer 2279.

The third cell insulating layer 2277 may entirely cover the data storage pattern DSP. In other words, the third cell insulating layer 2277 may cover the upper surface and side surface of the data storage pattern DSP.

The data storage pattern DSP may be connected to the first cell wiring 2262 via the first cell wiring contact 2261, and the first cell wiring 2262 may be connected to the second cell wiring 2264 via the second cell wiring contact 2263.

The first cell wiring contact 2261, the first cell wiring 2262, the second cell wiring contact 2263, and the second cell wiring 2264 may include metals such as copper Cu, aluminum Al, tungsten W, titanium Ti, tantalum Ta, or combination thereof.

The semiconductor device may further include an upper wiring structure 2370 positioned on the fourth cell insulating layer 2279.

The upper wiring structure 2370 may include an upper wiring layer 2371, an upper wiring hydrogen diffusion layer 2372, and an upper wiring hydrogen diffusion blocking layer 2373. The upper wiring structure 2370 may be positioned in the cell region CAR and/or peripheral region PAR. Accordingly, the upper wiring layer 2371, upper wiring hydrogen diffusion layer 2372, and upper wiring hydrogen diffusion blocking layer 2373 may also be positioned in the cell region CAR and/or peripheral region PAR.

The upper wiring layer 2371 may be positioned within the upper wiring hydrogen diffusion blocking layer 2373. The upper wiring layer 2371 may be in contact with the upper surface of the second cell wiring 2264. The upper wiring layer 2371 may be electrically connected to the first cell wiring 2262 and the second cell wiring 2264. For example, the upper width of the upper wiring layer 2371 may be shorter than the lower width.

For example, the upper wiring layer 2371 may include tungsten (W), titanium (Ti), tantalum (Ta), or nitrides thereof. In some implementations, the upper wiring layer 2371 may include a different conductive material than the first cell wiring 2262 and the second cell wiring 2264. For example, the first cell wiring 2262 and the second cell wiring 2264 may include a first metal, and the upper wiring layer 2371 may include a second metal different from the first metal. For example, the upper wiring layer 2371 may include aluminum (Al).

The upper wiring hydrogen diffusion layer 2372 may be positioned on the upper wiring layer 2371. The upper wiring hydrogen diffusion layer 2372 may conformally cover the upper surface of the upper wiring layer 2371. The upper wiring hydrogen diffusion layer 2372 may be positioned within the upper wiring hydrogen diffusion blocking layer 2373.

The upper wiring hydrogen diffusion layer 2372 may include an insulating material and hydrogen. In other words, the upper wiring hydrogen diffusion layer 2372 may be a hydrogen-rich (H-rich) insulating layer.

The upper wiring hydrogen diffusion layer 2372, through annealing, may allow for hydrogen present in the upper wiring hydrogen diffusion layer 2372 to be supplied to the cell region CAR via the data storage pattern DSP, diffusing to the boundary between the gate insulation pattern GOX and the first and the second active patterns AP1, AP2 via the first and the second word lines WL1, WL2.

For example, when the gate insulating pattern GOX includes silicon dioxide (SiO₂), and the first and second active patterns AP1, AP2 include silicon (Si), dangling bonds existing at the interface between the silicon dioxide (SiO₂) and silicon (Si) may be passivated with hydrogen. The upper wiring hydrogen diffusion layer 2372 may still include hydrogen even after diffusing hydrogen through annealing.

For example, an annealing process for diffusing hydrogen may be performed at a pressure of 10 Torr to 40 Torr, for example, 20 Torr to 30 Torr, for 15 minutes to 60 minutes, for example, 30 minutes to 45 minutes, at a temperature of 400 °C to 475 °C, for example, 375 °C to 400 °C. The annealing process may be conducted at a temperature below the temperature range that induces crystallization of the material of the first and second active patterns AP1, AP2 for example, below 600 °C.

The insulating material of the upper wiring hydrogen diffusion layer 2372 may include silicon nitride, silicon oxide, tetraethylortho silicate (TEOS), or a combination thereof. For example, by depositing SiH₄ and O₂ as raw materials, a hydrogen-rich upper wiring hydrogen diffusion layer 2372 including silicon oxide and hydrogen may be formed. In addition, by depositing SiH₄ and NH₃ as raw materials, a hydrogen-rich upper wiring hydrogen diffusion layer 2372 including silicon nitride and hydrogen may be formed. At this time, the deposition may use methods such as Atomic Pressure CVD (APCVD), Low Pressure CVD (LPCVD), Plasma Enhanced CVD (PECVD), or High Density Plasma CVD (HDPCVD). Alternatively, after depositing silicon oxide or silicon nitride, hydrogen can be plasma doped into the silicon oxide or silicon nitride to form a hydrogen-rich upper wiring hydrogen diffusion layer 2372.

For example, the upper wiring hydrogen diffusion layer 2372 may be a tetraethylortho silicate (TEOS) layer including TEOS, and the upper wiring hydrogen diffusion layer 2372 may be an HDP layer including high density plasma CVD (HDP CVD) dielectric material.

The upper wiring hydrogen diffusion layer 2372 may include hydrogen, deuterium, tritium, or a combination thereof. Hydrogen may be a hydrogen atom or a hydrogen molecule. Since deuterium or tritium is heavier than hydrogen, when the upper wiring hydrogen diffusion layer 2372 includes deuterium or tritium, it can reduce the loss of deuterium or tritium into the air compared to when it includes hydrogen. For example, the upper wiring hydrogen diffusion layer 2372 may include 90 % or more of hydrogen with respect to the sum of hydrogen, deuterium, and tritium.

As an example, the upper wiring hydrogen diffusion layer 2372 may include hydrogen in an amount of greater than 0 at% based on a total of the upper wiring hydrogen diffusion layer 2372, for example, 1 at% or more, 2 at% or more, 3 at% or more, or 4 at% or more, it may include hydrogen in an amount of 5 at% or less, for example, 4 at% or less, 3 at% or less, or 2 at% or less, and for example, it may include hydrogen in an amount of greater than 0 at% and less than or equal to 5 at%.

In this case, the upper wiring hydrogen diffusion layer 2372 may have a lower hydrogen concentration than that of the gate hydrogen diffusion pattern 2145. Accordingly, the principal source of hydrogen may be the gate hydrogen diffusion pattern 2145, and the upper wiring hydrogen diffusion layer 2372 may serve as a supplemental source of hydrogen. As previously mentioned, hydrogen diffusion from the upper wiring hydrogen diffusion layer 2372, due to its path of diffusion, may induce reliability degradation in the upper wiring structure 2370 and the data storage pattern DSP. Therefore, the upper wiring hydrogen diffusion layer 2372 may serve to support the gate hydrogen diffusion pattern 2145.

The upper wiring hydrogen diffusion blocking layer 2373 may be positioned on the fourth cell insulating layer 2279. The upper wiring hydrogen diffusion blocking layer 2373 may cover the upper wiring layer 2371 and the upper wiring hydrogen diffusion layer 2372.

For example, the upper wiring hydrogen diffusion blocking layer 2373 may have lower hydrogen diffusivity than the upper wiring hydrogen diffusion layer 2372. The upper wiring hydrogen diffusion blocking layer 2373 may include silicon nitride with low hydrogen diffusivity. The hydrogen concentration in the upper wiring hydrogen diffusion blocking layer 2373 may be lower than that in the upper wiring hydrogen diffusion layer 2372. In other words, the formation of the upper wiring hydrogen diffusion blocking layer 2373 may not involve using a hydrogen source such as SiH₄ or NH₃. The upper wiring hydrogen diffusion blocking layer 2373 may include 1 at% or less of hydrogen across the entire layer or may not include any hydrogen. The upper wiring hydrogen diffusion blocking layer 2373 may prevent hydrogen from the upper wiring hydrogen diffusion layer 2372 from spreading upwards, for example, outward from the semiconductor device.

A passivation layer 2390 may be positioned on the upper wiring structure 2370. For example, the passivation layer 2390 may include silicon nitride (SiN). The hydrogen permeability of the passivation layer 2390 may be higher than the hydrogen permeability of the upper wiring hydrogen diffusion blocking layer 2373.

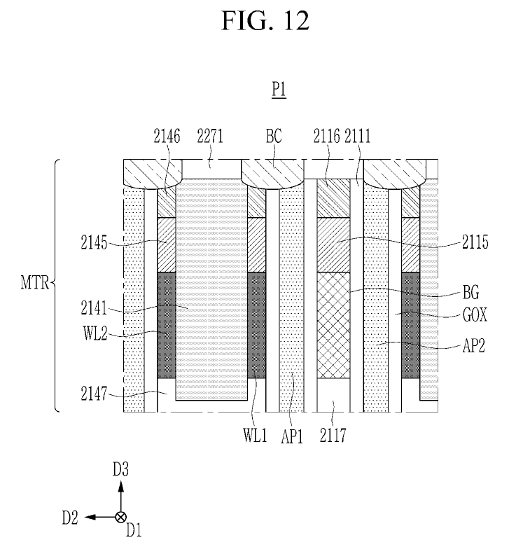

FIG. 12 is a cross-sectional view of a semiconductor device according to some implementations, corresponding to FIG. 11. For convenience of explanation, the description will focus on points that differ from those described using FIGS. 8 to 11.

Referring to FIG. 12, a semiconductor device may further include a gate hydrogen diffusion blocking layer 2146 on the gate hydrogen diffusion pattern 2145. The gate hydrogen diffusion blocking layer 2146 may cover the gate hydrogen diffusion pattern 2145. The gate hydrogen diffusion blocking layer 2146 may be positioned under the storage contact BC and may be positioned between the gate hydrogen diffusion pattern 2145 and the storage contact BC.

For example, the gate hydrogen diffusion blocking layer 2146 may have lower hydrogen diffusivity than the gate hydrogen diffusion pattern 2145. The gate hydrogen diffusion blocking layer 2146 may include silicon nitride, which has low hydrogen diffusivity. The gate hydrogen diffusion blocking layer 2146 may have a lower hydrogen concentration than the gate hydrogen diffusion pattern 2145. In other words, during the formation of the gate hydrogen diffusion blocking layer 2146, a hydrogen source, such as SiH₄ or NH₃, may not be used. The gate hydrogen diffusion blocking layer 2146 may include 1 at% or less of hydrogen across the entire gate hydrogen diffusion blocking layer 2146 or may not include hydrogen. The gate hydrogen diffusion blocking layer 2146 may prevent hydrogen from diffusing upwards from the gate hydrogen diffusion pattern 2145, for example, the data storage pattern DSP or the upper wiring structure 2370.

Moreover, the semiconductor device may further include back a gate hydrogen diffusion blocking layer 2116 on the back gate hydrogen diffusion pattern 2115. The back gate hydrogen diffusion blocking layer 2116 may cover the back gate hydrogen diffusion pattern 2115. The back gate hydrogen diffusion blocking layer 2116 may be positioned below the storage contact BC, and it may be positioned between the back gate hydrogen diffusion pattern 2115 and the storage contact BC.

For example, the back gate hydrogen diffusion blocking layer 2116 may have lower hydrogen diffusivity than the back gate hydrogen diffusion pattern 2115. The back gate hydrogen diffusion blocking layer 2116 may include silicon nitride that has small hydrogen diffusivity. The back gate hydrogen diffusion blocking layer 2116 may have a lower hydrogen concentration than the back gate hydrogen diffusion pattern 2115. In other words, during the formation of the back gate hydrogen diffusion blocking layer 2116, hydrogen sources such as SiH₄ or NH₃ may not be used. The back gate hydrogen diffusion blocking layer 2116 may include 1 at% or less of hydrogen across the entire back gate hydrogen diffusion blocking layer 2116 or may not include hydrogen. The back gate hydrogen diffusion blocking layer 2116 may prevent hydrogen from diffusing upwards from the back gate hydrogen diffusion pattern 2115, for example, to the data storage pattern DSP or the upper wiring structure 2370.

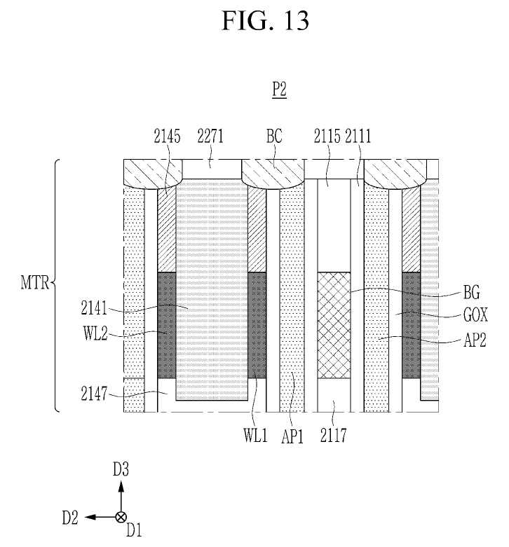

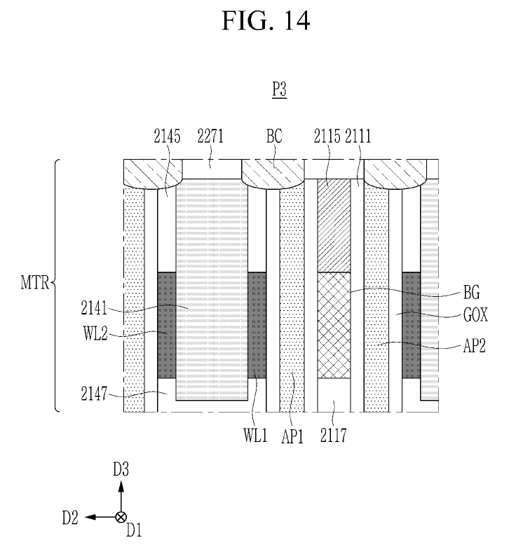

FIGS. 13 and 14 are cross-sectional views of a semiconductor device according to some implementations, corresponding to FIG. 11. For the convenience of explanation, the description will focus on points that differ from those described using FIGS. 8 to 11.

Referring to FIG. 11, it is illustrated that the gate hydrogen diffusion pattern 2145 and the back gate hydrogen diffusion pattern 2115 include an insulating material and hydrogen, representing a hydrogen-rich (H-rich) insulating layer.

Referring to FIG. 13, the gate hydrogen diffusion pattern 2145 may be a hydrogen-rich (H-rich) insulating layer including an insulating material and hydrogen, whereas the back gate hydrogen diffusion pattern 2115 may be a general insulating layer including an insulating material and not including hydrogen. Here, the general insulating layer not including hydrogen refers to a situation where it does not include any hydrogen or includes a small amount of hydrogen due to diffusion and so forth.

Referring to FIG. 14, the back gate hydrogen diffusion pattern 2115 may be a hydrogen-rich (H-rich) insulating layer that includes insulating material and hydrogen, whereas the gate hydrogen diffusion pattern 2145 may be a general insulating layer that includes insulating material and does not include hydrogen.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The implementations of the present disclosure have been detailed above, but the scope of rights of the present disclosure is not limited thereto. Various modifications and improvements by those skilled in the art using the basic concept of the present disclosure defined in the following claims also belong to the scope of rights of the present disclosure.

What is claimed is:

1. A semiconductor device comprising
a substrate including a cell active pattern,
a cell gate structure on the cell active pattern, and
a bit line structure connected to the cell active pattern,
wherein the cell gate structure includes a cell gate insulating layer on the cell active pattern, a cell gate conductive layer on the cell gate insulating layer, and a cell gate capping layer on the cell gate conductive layer, the cell gate capping layer including an insulating material and hydrogen.

2. The semiconductor device of claim 1, wherein the insulating material of the cell gate capping layer includes at least one of silicon nitride, silicon oxide, or tetraethylortho silicate.

3. The semiconductor device of claim 1, wherein the cell gate structure includes a cell gate hydrogen diffusion blocking layer on the cell gate capping layer,
wherein the cell gate hydrogen diffusion blocking layer includes silicon nitride, and
wherein the cell gate hydrogen diffusion blocking layer has a lower hydrogen diffusivity than the cell gate capping layer.

4. The semiconductor device of claim 1, wherein the cell gate capping layer includes the insulating material in which the hydrogen is plasma doped.

5. The semiconductor device of claim 1, wherein the cell gate structure includes a second conductive layer on the cell gate conductive layer, the second conductive layer including polysilicon.

6. The semiconductor device of claim 1, wherein the semiconductor device includes:
a data storage pattern connected to the cell active pattern, and
an upper wiring structure on the data storage pattern,
wherein the upper wiring structure includes an upper wiring layer and an upper wiring hydrogen diffusion layer, wherein the upper wiring hydrogen diffusion layer covers the upper wiring layer and wherein the upper wiring hydrogen diffusion layer includes an insulating material and hydrogen, and
wherein the insulating material of the upper wiring hydrogen diffusion layer includes at least one of silicon nitride, silicon oxide, or tetraethylortho silicate.

7. The semiconductor device of claim 6, wherein the upper wiring structure includes an upper wiring hydrogen diffusion blocking layer on the upper wiring hydrogen diffusion layer,
wherein the upper wiring hydrogen diffusion blocking layer includes silicon nitride, and
wherein the upper wiring hydrogen diffusion blocking layer has a lower hydrogen diffusivity than the upper wiring hydrogen diffusion layer.

8. The semiconductor device of claim 6, wherein a hydrogen concentration in the cell gate capping layer is greater than a hydrogen concentration in the upper wiring hydrogen diffusion layer.

9. The semiconductor device of claim 6, wherein the semiconductor device includes
the substrate including a cell region and a peripheral region, wherein the cell region includes the cell active pattern;
a peripheral gate structure in the peripheral region of the substrate;
the upper wiring structure on the peripheral gate structure; and
a dielectric layer below the upper wiring structure in the cell region of the substrate,
wherein the dielectric layer includes a first layer including aluminum oxide, a second layer including zirconium, or a composite layer, the composite layer having the first layer and the second layer that are alternately laminated, and
wherein the semiconductor device is free of the dielectric layer in the peripheral region of the substrate between the peripheral gate structure and the upper wiring structure, wherein the semiconductor device in the peripheral region of the substrate is free of the first layer including aluminum oxide, the second layer including zirconium, or the composite layer.

10. The semiconductor device of claim 9, wherein the data storage pattern includes a lower electrode connected to the cell active pattern, an upper electrode spaced apart from the lower electrode, and a data storage pattern dielectric layer between the lower electrode and the upper electrode, wherein the data storage pattern dielectric layer includes a first layer including aluminum oxide, a second layer including zirconium, or a composite layer where the first layer and the second layer are alternately laminated.

11. A semiconductor device comprising
a substrate,
a bit line on the substrate and extended in a second direction different from a first direction,
a first word line and a second word line on the bit line, extended in the first direction, and alternately spaced apart from each other in the second direction,
a first active pattern and a second active pattern on the bit line, spaced apart from each other in the first direction, wherein the first active pattern and the second active pattern are between the first word line and the second word line, wherein the first active pattern is closer to the first word line than to the second word line and wherein the second active pattern is closer to the second word line than to the first word line,
a back gate electrode on the bit line, extended in the first direction, and between the first active pattern and the second active pattern,
a gate hydrogen diffusion pattern on the first word line and the second word line, and
a back gate hydrogen diffusion pattern on the back gate electrode,
wherein the gate hydrogen diffusion pattern and the back gate hydrogen diffusion pattern include an insulating material and hydrogen.

12. The semiconductor device of claim 11, wherein the insulating material of the gate hydrogen diffusion pattern and the back gate hydrogen diffusion pattern includes at least one of silicon nitride, silicon oxide, or tetraethylortho silicate.

13. The semiconductor device of claim 11, wherein the semiconductor device includes a first hydrogen diffusion blocking layer on the gate hydrogen diffusion pattern,
wherein the first hydrogen diffusion blocking layer includes silicon nitride, and
wherein the first hydrogen diffusion blocking layer has a lower hydrogen diffusivity than the gate hydrogen diffusion pattern,
wherein the semiconductor device includes a second hydrogen diffusion blocking layer on the back gate hydrogen diffusion pattern,
wherein the second hydrogen diffusion blocking layer includes silicon nitride, and
wherein the second hydrogen diffusion blocking layer has a lower hydrogen diffusivity than the back gate hydrogen diffusion pattern.

14. The semiconductor device of claim 11, wherein the gate hydrogen diffusion pattern and the back gate hydrogen diffusion pattern include the insulating material in which the hydrogen is plasma doped.

15. The semiconductor device of claim 11, wherein the semiconductor device includes a data storage pattern on the first active pattern and the second active pattern, and
an upper wiring structure on the data storage pattern,
wherein the upper wiring structure includes
an upper wiring layer,
an upper wiring hydrogen diffusion layer including an insulating material and hydrogen and covering the upper wiring layer, and
an upper wiring hydrogen diffusion blocking layer on the upper wiring hydrogen diffusion layer,
wherein the insulating material of the upper wiring hydrogen diffusion layer includes at least one of silicon nitride, silicon oxide, or tetraethylortho silicate,
wherein the upper wiring hydrogen diffusion blocking layer includes silicon nitride, and
wherein the upper wiring hydrogen diffusion blocking layer has a lower hydrogen diffusivity than the upper wiring hydrogen diffusion layer.

16. A semiconductor device comprising
a substrate,
a bit line on the substrate, and extended in a second direction different from a first direction,
a first word line and a second word line on the bit line, extended in the first direction, and alternately spaced apart from each other in the second direction,
a first active pattern and a second active pattern on the bit line, spaced apart in the first direction, wherein the first active pattern and the second active pattern are between the first word line and the second word line, and wherein the first active pattern is closer to the first word line than to the second word line and wherein the second active pattern is closer to the second word line than to the first word line,
a gate hydrogen diffusion pattern on the first word line and the second word line, and
a hydrogen diffusion blocking layer on the gate hydrogen diffusion pattern,
wherein the hydrogen diffusion blocking layer has a lower hydrogen diffusivity than the gate hydrogen diffusion pattern.

17. The semiconductor device of claim 16, wherein the gate hydrogen diffusion pattern includes an insulating material which includes at least one of silicon nitride, silicon oxide, or tetraethylortho silicate.

18. The semiconductor device of claim 16, wherein the hydrogen diffusion blocking layer includes silicon nitride.

19. The semiconductor device of claim 16, wherein the gate hydrogen diffusion pattern includes an insulating material in which the hydrogen is plasma doped.

20. The semiconductor device of claim 16, wherein the semiconductor device includes a data storage pattern on the first active pattern and the second active pattern, and
an upper wiring structure on the data storage pattern,
wherein the upper wiring structure includes
an upper wiring layer,
an upper wiring hydrogen diffusion layer that covers the upper wiring layer and includes an insulating material and hydrogen, and
an upper wiring hydrogen diffusion blocking layer on the upper wiring hydrogen diffusion layer,
wherein the insulating material of the upper wiring hydrogen diffusion layer includes at least one of silicon nitride, silicon oxide, or tetraethylortho silicate,
wherein the upper wiring hydrogen diffusion blocking layer includes silicon nitride, and
wherein the upper wiring hydrogen diffusion blocking layer has a lower hydrogen diffusivity than the upper wiring hydrogen diffusion layer.
